(19) United States
(12) Patent Application Publication
(10) Pub. No.: US 2021/0218238 A1
(43) Pub. Date: Jul. 15, 2021

(54) CABLE INSTALLATION METHOD AND SYSTEM

(71) Applicant: COMMSCOPE TECHNOLOGIES LLC, Hickory, NC (US)

(72) Inventor: Barry Wayne ALLEN, Siler City, NC (US)

(73) Assignee: COMMSCOPE TECHNOLOGIES LLC, Hickory, NC (US)

(21) Appl. No.: 17/251,721

(22) PCT Filed: Jun. 11, 2019
(86) PCT No.: PCT/US2019/036525

§ 371 Date: Dec. 11, 2020

Related U.S. Application Data
(60) Provisional application No. 62/684,098, filed on Jun. 12, 2018.

(51) Int. Cl. H02G 15/013; H02G 3/08; H05K 5/02

(52) U.S. Cl. CPC H02G 15/013; H05K 5/0221; H02G 3/083

(57) ABSTRACT

The present disclosure relates to a cable insertion system and method that allows a cable to be inserted through a sealant of an enclosure cable sealing arrangement without de-pressurizing the sealant.

### CROSS-REFERENCE TO RELATED APPLICATION

This application is being filed on Jun. 11, 2019 as a PCT International Patent Application and claims the benefit of U.S. Patent Application Ser. No. 62/684,098, filed on Jun. 12, 2018, the disclosure of which is incorporated herein by reference in its entirety.

### BACKGROUND

Telecommunications systems typically employ a network of telecommunications cables capable of transmitting large volumes of data and voice signals over relatively long distances. The telecommunications cables can include fiber optic cables, electrical cables, or combinations of electrical and fiber optic cables. A typical telecommunications network also includes a plurality of telecommunications enclosures integrated throughout the network of telecommunications cables. The telecommunications enclosures are adapted to house and protect telecommunications components such as splices, termination panels, power splitters and wavelength division multiplexers. It is often preferred for the telecommunications enclosures to be re-enterable. The term “re-enterable” means that the telecommunications enclosures can be reopened to allow access to the telecommunications components housed therein without requiring the removal and destruction of the telecommunications enclosures. For example, certain telecommunications enclosures can include separate access panels that can be opened to access the interiors of the enclosures, and then closed to re-seal the enclosures. Other telecommunications enclosures take the form of elongated sleeves formed by wrap-around covers or half-shells having longitudinal edges that are joined by clamps or other retainers. Still other telecommunications enclosures include two half-pieces that are joined together through clamps, wedges or other structures.

Telecommunications enclosures are typically sealed to inhibit the intrusion of moisture or other contaminants. Pressurized gel-type seals have been used to effectively seal the locations where telecommunications cables enter and exit telecommunications enclosures. Example pressurized gel-type seals are disclosed by document EP 0442941 B1 and document EP 0587616 B1. Both of these documents disclose gel-type cable seals that are pressurized through the use of threaded actuators. Document U.S. Pat. No. 6,046,406 discloses a cable seal that is pressurized through the use of an actuator including a cam lever. While pressurized cable seals have generally proven to be effective, improvements in this area are still needed.

### SUMMARY

One aspect of the present disclosure relates to a sealed enclosure including a housing defining an opening and a cable sealing arrangement positioned within the opening. The cable sealing arrangement engages the housing to seal the opening. The cable sealing arrangement includes a block of gel defining a total gel volume. The cable sealing arrangement includes at least first and second gel sections which coincide with at least a portion of the block of gel. The cable sealing arrangement includes a cable pass-through location defined at an interface between the first and second gel sections. The first and second gel sections are configured to form seals about cables routed axially through the cable pass-through location. The gel volume has a first outer boundary which is the outer boundary of the block of gel when the gel block is not sealing about a cable or cables. Open space is provided to accommodate deformation of the block of gel when the gel is pressurized with one or more cables routed through the cable pass-through location. The open space has a volume that is at least 5 percent as large as the total gel volume.

Another aspect of the present disclosure relates to a cable installation technique and system that allows fiber optic cables to be installed within a cable sealing arrangement without de-pressurizing the cable sealing arrangement and without disturbing any cables that have already been sealed within the cable sealing arrangement. In certain examples, cables such as drop cables or beater cables can be added to the cable sealing arrangement without requiring significant disassembly of the closure and/or the cable sealing arrangement. In certain examples, a detackifier such as a cleaning surfactant (e.g., a soap or detergent) can be used to facilitate the cable installation process.

A variety of additional inventive aspects will be set forth in the description that follows. The inventive aspects can relate to individual features and to combinations of features. It is to be understood that both the forgoing general description and the following detailed description are exemplary and explanatory only and are not restrictive of the broad inventive concepts upon which the embodiments disclosed herein are based.

### BRIEF DESCRIPTION OF THE DRAWINGS

The accompanying drawings, which are incorporated in and constitute a part of the description, illustrate several aspects of the present disclosure. A brief description of the drawings is as follows:

FIG. 1 depicts a closure in accordance with the principles of the present disclosure;

FIG. 2 is cross-sectional view cut through a gel block of the closure of FIG. 2, the gel block is used in combination with open sided volume compensation plates;

FIG. 3 depicts a gel block suitable for use with the closure of FIG. 1, the gel block is shown in combination with sealed/covered volume compensation plates;

FIG. 4 is an exploded view of the one of the sealed volume compensating plates;

FIG. 5 is an assembled view of the sealed volume compensating plate of FIG. 4;

FIG. 6 depicts a gel block suitable for use with the closure of FIG. 1, the gel block is shown in combination with volume compensation plates having openings filled with resilient materials such as foam;

FIG. 7 is an exploded view of one of the volume compensation plates of FIG. 6;

FIG. 8 depicts a gel block suitable for use with the closure of FIG. 1, the gel block is shown in combination with volume compensation plates having open gel receiving space defined between tapered projections;

FIG. 9 shows one of the volume compensation plates of FIG. 8;

FIG. 10 shows another volume compensation arrangement;

FIG. 11 shows a sealed volume compensation plate having tapered projections;

FIG. 12 depicts a cable sealing arrangement in accordance with the principles of the present disclosure;

FIG. 13 depicts a volume compensating arrangement that is part of the cable sealing arrangement of FIG. 12;

FIG. 14 is a cross-sectional view taken through the cable sealing arrangement of FIG. 12;

FIG. 15 depicts a telecommunications enclosure in accordance with the principles of the present disclosure, the telecommunications enclosure is environmentally sealed and if fully latched in a closed position;

FIG. 16 shows the telecommunications enclosure of FIG. 15 having a first section of the enclosure unlatched and a second section of the enclosure latched;

FIG. 17 shows the telecommunications enclosure of FIG. 16 with the second section of the enclosure in an open configuration to provide access to the interior of the enclosure for operations such as optical patching and/or optical splicing;

FIG. 18 is a cross-sectional view through the first section of the telecommunications enclosure of FIG. 15 with the first section opened and with no gel present at the first section;

FIG. 19 is a cross-sectional view through the first section of the telecommunications enclosure of FIG. 15 with cable sealing gel present within the first section and with the gel not yet pressurized;

FIG. 20 is a cross-sectional view through the first section of the enclosure of FIG. 15 with the first section clamped closed and the cable sealing get pressurized;

FIG. 21 is a cross-sectional view through the first section of the enclosure of FIG. 15 with the gel sealing arrangement pressurized and with a cable sealed within the cable sealing arrangement;

FIG. 22 is a cross-sectional view through the sealant pressurizing section of the enclosure of FIG. 15 with the sealant arrangement pressurized and fully loaded with cables;

FIG. 23 shows the enclosure of FIG. 15 with the main section of the enclosure open and with the gel pressurizing section of the enclosure clamped closed, a cable is shown being pushed through the gel sealing arrangement;

FIG. 24 shows the enclosure of FIG. 23 with the main section of the enclosure closed after the cable has been installed through the gel sealing arrangement;

FIG. 25 shows the enclosure of FIG. 24 with the main section of the enclosure again open and with drop cables being installed through the gel sealing arrangement while the sealant pressurizing section of the enclosure remains clamped closed;

FIG. 26 shows the enclosure of FIG. 25 with the main section of the enclosure closed after the drop cables have been installed through the gel sealing arrangement;

FIG. 27 shows the enclosure of FIG. 26 with the main section of the enclosure again open and with further drop cables and feeder cables being installed through the gel sealing arrangement without requiring pressurizing section of the closure to be open;

FIGS. 28A and 28B show the enclosure of FIG. 15 and also show a cable installation tool for facilitating installing a cable through the cable sealing arrangement of the enclosure without de-pressurizing the cable sealing arrangement;

FIGS. 29A and 29B show the cable installation tool of FIGS. 28a and 28b inserted within the gel sealing arrangement of the enclosure;

FIGS. 30A and 30B show a cable guide portion of the cable installation tool inserted within the gel sealing arrangement and a core of the insertion tool removed from the cable guide;

FIGS. 31A and 31B show a cable which has been prepared for insertion through the cable guide that was preloaded within the cable sealing arrangement;

FIGS. 32A and 32B show the prepared cable of FIGS. 31A and 31B in the process of being inserted through the cable guide that has been preloaded into the cable sealing arrangement;

FIGS. 33A and 33B show the continued insertion of the prepared fiber optic cable through the cable guide;

FIGS. 34A and 34B show removal of the cable guide from the cable sealing arrangement;

FIGS. 35A and 35B show removal of the cable guide from the cable;

FIGS. 36A and 36B show the fiber optic cable sealed within the cable sealing arrangement while the main section of the enclosure remains open;

FIG. 37 shows the fiber optic cable sealed within the gel sealing arrangement with the main section of the enclosure clamped closed;

FIG. 38 shows other sealant/gel volume compensation structures in accordance with the principles of the present disclosure;

FIG. 39 shows the gel/sealant volume compensation structures of FIG. 38 in combination with a volume of gel;

FIG. 40 shows the gel/volume compensation structures and sealant of FIG. 39 with a cable sealed therein;

FIG. 41 depicts an enclosure in accordance with the principles of the present disclosure suitable for using cable sealing units such as shown at FIG. 40;

FIG. 42 is an end view of the enclosure of FIG. 41;

FIG. 43 shows the cable sealing arrangement of the enclosure of FIG. 41 which includes plurality of cable sealing units loaded within pockets defined by one or more cable pressurization structures;

FIG. 44 is a cross-sectional view showing one of the cable sealing units prior to receiving a cable there through; and

FIG. 45 shows the cable sealing unit of FIG. 44 with a cable sealed therein.

### DETAILED DESCRIPTION

Reference will now be made in detail to exemplary aspects of the present disclosure that are illustrated in the accompanying drawings. Wherever possible, the same reference numbers will be used throughout the drawings to refer to the same or like parts.

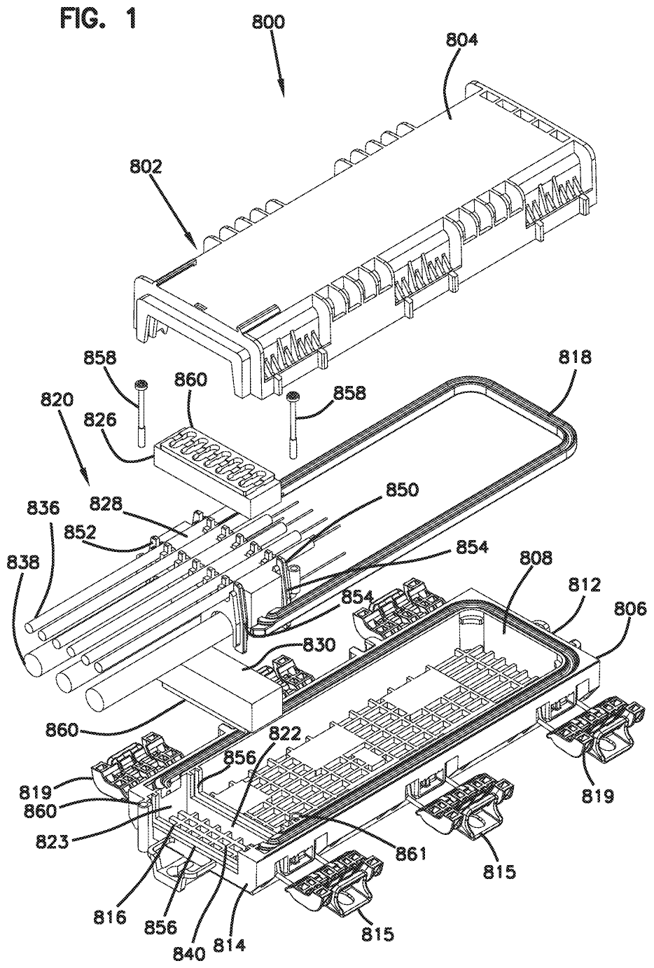

FIG. 1 depicts sealed enclosure 800 having cable sealing in accordance with aspects of the present disclosure. The enclosure 800 includes a housing 802 including first and second housing pieces 804, 806 (e.g., a cover and a base) that mate to defined an interior 808 of the housing 802 the housing pieces 804, 806 each extend from a first end 812 to a second end 814 of the housing 802. The first end 812 is depicted as closed and the second end 814 defines an opening 816 through which cables can be routed in and out of the housing. A perimeter seal 818 extends around a perimeter of the housing 802 and is adapted to seal between the pieces 804, 806 when the pieces 804, 806 are secured together. In certain examples, the pieces 804, 806 can be connected together by a slideable hinge as disclosed in PCT Publication No. WO 2017/046187, which is hereby incorporated by reference. Clamps 819 are provided at both elongate sides of the housing for securing the first and second housing pieces 804, 806 together and for compressing the perimeter seal 818. In other examples, both ends of the housing 802 can be configured for passing through cables. In other examples, other housing shapes (e.g., shapes that are not elongate) can be used.

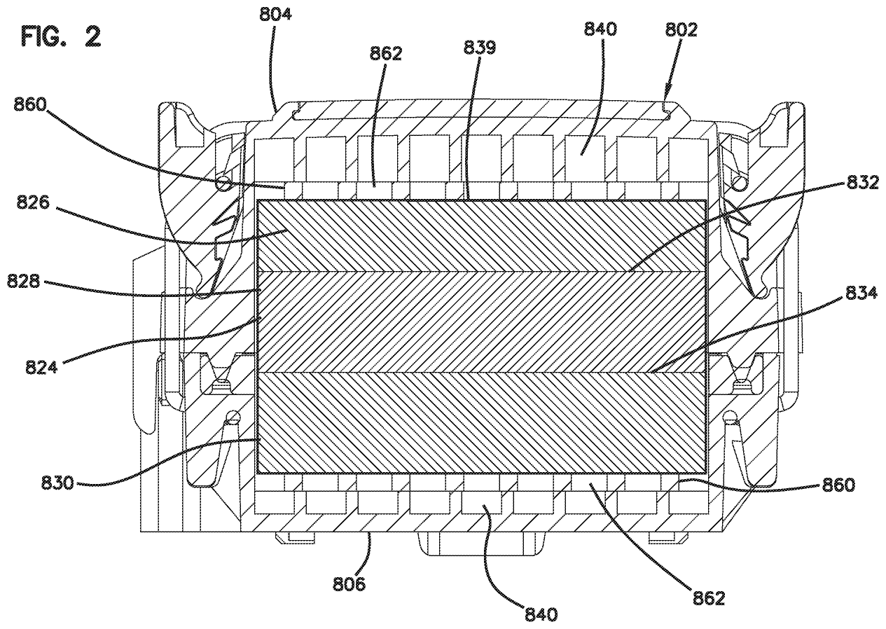

A cable sealing arrangement 820 positioned within the opening 816 in communication/contact with ends of the perimeter seal 818. The cable sealing arrangement 820 engages the housing 802 (e.g., axial seal faces 822 of the housing; or lateral facing faces of the housing 823) and the perimeter seal 818 to seal about the opening 816. The cable sealing arrangement 820 including a block of gel 824 defining a total gel volume. The cable sealing arrangement 820 includes first, second and third gel sections 826, 828, 830 which define the block of gel 824. The second gel section 828 is between the first and second gel sections 826, 830. The cable sealing arrangement 820 includes a first cable pass-through location 832 defined at an interface between the first and second gel sections 826, 828; and a second cable pass-through location 834 is defined at an interface between the second and third gel sections 828, 830. Drop cables 836 are shown routed axially through the first cable pass-through location 832 and feeder cables 838 are shown routed axially through the second cable pass-through location 834. The first and second gel sections 826, 828 are configured to form seals about drop cables 836 and the second and third gel sections 828, 830 are configured to form seals about the feeder cables 838. The gel volume has first outer boundary 839 (see FIG. 2) which is the outer boundary of the block of gel 824 when the gel has not been deformed to accommodate any cables at the pass-through location or locations. FIG. 2 shows the cable sealing arrangement enclosed within the end of the housing but with no cables routed through the cable sealing arrangement, and therefore depicted the first outer boundary 839. The first outer boundary can also be referred to as a pre-cable sealing outer boundary or an unoccupied cable sealing boundary. As shown at FIG. 2, open space 840 is provided to accommodate deformation of the block of gel 824 when the gel is pressurized while one or more cables is present at the cable pass-through location. In one example, the open space 840 has a volume that is at least 5 percent as large as the total gel volume. In another example, the open space 840 has a volume that is at least 10 percent as large as the total gel volume. In another example, the open space 840 has a volume that is at least 12.5 percent as large as the total gel volume. In still another example, the open space 840 has a volume that is at least 15 percent as large as the total gel volume.

In other examples, the gel sealing arrangement can include only one cable pass-through location, or more than two cable pass-through locations. In certain examples, the first and third gel sections 826, 830 can be respectively molded (e.g., injection molded) within portions of the first and second housing pieces 804, 806 that define the opening 816 (e.g., in the volume defined by the axial faces and the lateral faces which effectively define gel receiving cavities). The gel of the cable sealing arrangement preferably has sealing and mechanical properties of the type disclosed in U.S. Pat. No. 8,642,891, which is hereby incorporated by reference in its entirety. In one example, the gel is a dry silicone gel.

In certain examples at least a portion of the open space 840 is located laterally outside the first outer boundary 839. In certain examples, a majority of the open space 840 is located laterally outside the first outer boundary 839. As depicted the open space 840 is defined laterally between the first outer boundary 839 and an interior surface of the housing 802. In the depicted, the open space 840 is defined at least in part by an open cell grid pattern 842 within the first and second housing pieces on opposite sides of the cable sealing arrangement 820 (e.g., laterally outside the first and third gel sections 826, 830).

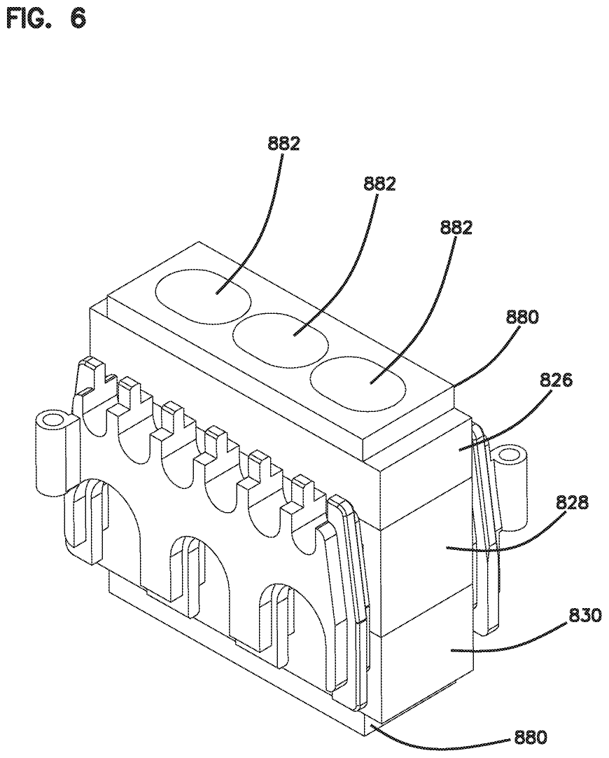

In certain examples, at least a portion of the open space is within the first outer boundary 839 at a location offset from the cable pass-through location. For example, at least a portion of the open space can be within the first outer boundary 839 at a location encapsulated within one of the first, second or third gel sections 826, 828, 830 at a location offset from the cable pass-through location. In one example, open space is provided within the second gel section 828. For example, a sealed volume compensator (e.g., see FIG. 5) can be embedded or otherwise positioned within the second gel section 828. Similar sealed volume compensators could also be positioned in the first and/or third gel sections 826, 830.

In one example, the block of gel 824 is pressed between the first and second housing pieces 804, 806 to fully pressurize and deform the cable sealing arrangement 820. In certain examples, the housing pieces 804, 806 are clamped by the perimeter clamps together to close the housing 802, and the perimeter clamps apply the necessary force for fully pressurizing the block of gel. In a preferred example, a dedicated actuator (i.e., an actuator provided only for pressurizing the cable sealing gel) is not provided for pressurizing the block of gel. In other examples, a dedicated actuator may be used. In a preferred example, a dedicated actuator including a spring (e.g., a coil spring) is not provided for maintaining the block of gel in compression. In some examples, springs may be integrated into the housing.

Referring to FIG. 2, no predefined cable receiving positions are defined by the first, second and third gel sections 826, 282, 830 at the cable pass-through locations 832, 834. In one example, the cable pass-through locations seals 832, 834 are sealed without requiring a plug in a condition in which the block of gel is pressurized and no cable is present at the cable pass-through location. In certain examples, a volume of gel displaced by a cabling passing through the block of gel is at least 90 percent of a total volume defined by the cabling within the block of gel. In certain examples, the volume of gel displaced by cabling passing through the block of gel is generally equal to the total volume defined by the cabling within the block of gel. In certain examples, the first and second cable pass-through location can accommodate cables having a diameter across a full range from 0-14 millimeters. In certain examples, the cable pass-through locations can each accommodate at least a 14 millimeter range in cable diameter.

Referring to FIG. 1, inner and outer axial containment walls 850, 852 are provided for axially containing the block of gel 824 during pressurization. In one example, the inner and outer axial containment walls 850, 852 are axially fixed relative to each other when the block of gel is pressurized. In one example, the inner and outer axial containment walls 850, 852 are axially fixed relative to the housing when the block of gel is pressurized. For example, the walls 850, 852 can each include peripheral portions 854 (i.e., laterally extending portions) that fit within peripheral slots 856 defined within the interior of the housing 802 by the first and second housing pieces 804, 806. Fasteners 856 such as bolts 858 can engage corresponding fastener openings 860 defined by the second housing piece 806 to secure the walls 850, 852 thereto.

Referring to FIG. 1, volume compensation plates 860 are positioned at the first outer boundary 839 of the block of gel. The volume compensation plates 860 each define a plurality of gel receiving openings 862 into which gel flows when the block of gel 824 is pressurized while cabling is present at one or more of the cable pass-through locations. The plates 860 are positioned between the interior of the housing 802 and the block of gel 826. One of the plates 860 is shown between the first gel section 826 and the first housing piece 804 and the other plate 860 is shown between the third gel section 830 and the second housing piece 806. The openings 862 allow gel to flow or extrude therethrough to move into the open space defined within the interior of the housing. In this way, space is provided for accommodating gel when the gel deforms during gel pressurization to conform to the shape of the fiber optic cables routed through the cable pass-through locations. In certain examples, at least some of the gel extrudes through the gel receiving openings 862 into a region defined between the housing and the volume compensation plate.

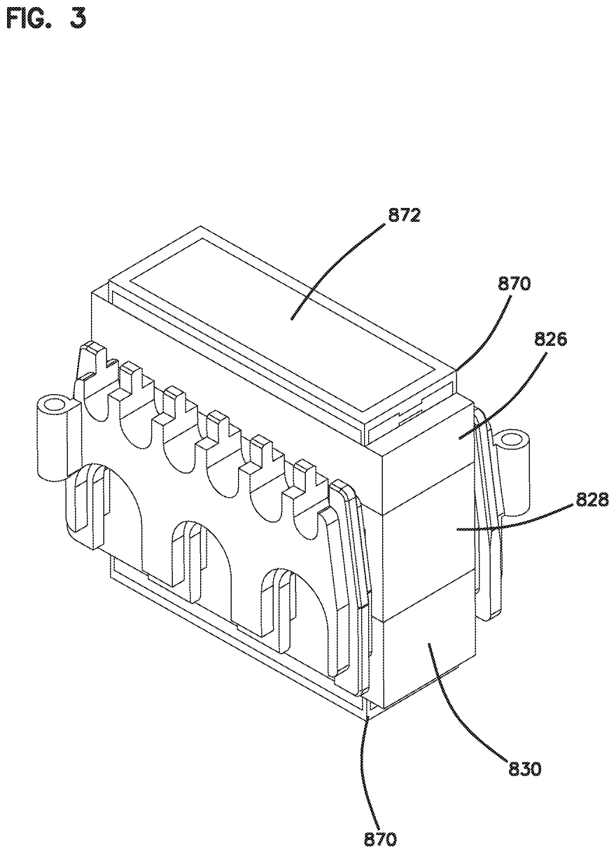

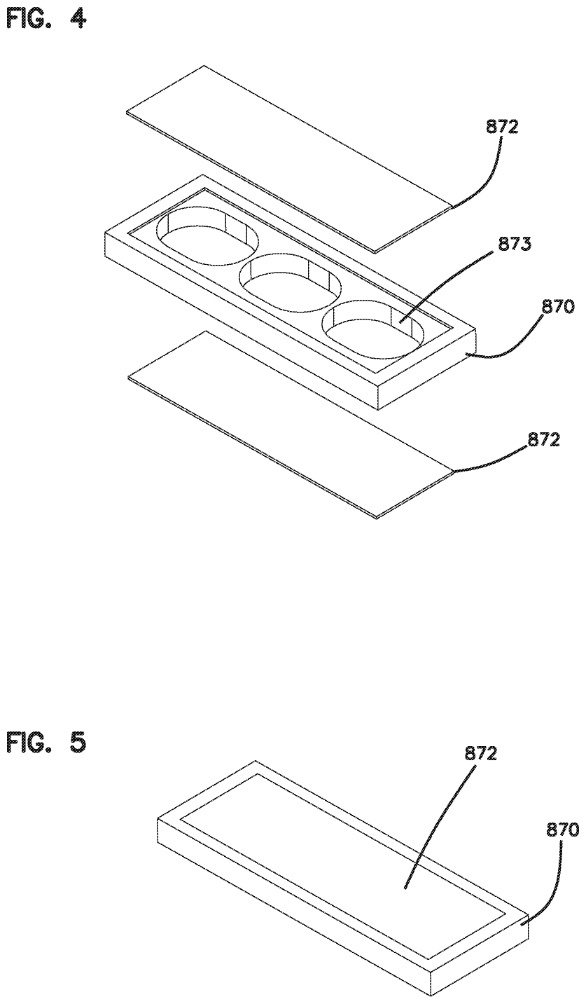

FIGS. 3-5 show another volume compensation plate 870 which has been modified to include cover layer 872 attached to the volume compensation plate 870 and which covers the gel receiving openings. The cover layer 872 layer flex, stretch or break to allow the portion of the gel to enter or pass-through the gel receiving openings when the gel is pressurized. The cover layers 872 prevent gel from flowing through the gel receiving openings 873 during manufacturing of the enclosure. For example, the layers 872 allow the first and third gel sections 826, 830 to be injection molded into the housing pieces 804, 806 without filling the gel receiving openings or the open space needed to receive gel during gel pressurization during the manufacturing process. In some examples, only one side of the plate 870 may be covered. The double sided covering version is useful for providing volume compensation (e.g., open space for receiving gel during gel pressurization) within a volume of gel. The gel receiving openings can pass through the volume compensation plate from a first side to a second side, and the cover layers which cover the gel receiving openings are attached to the volume compensation plate at the first and second sides of the volume compensation plate.

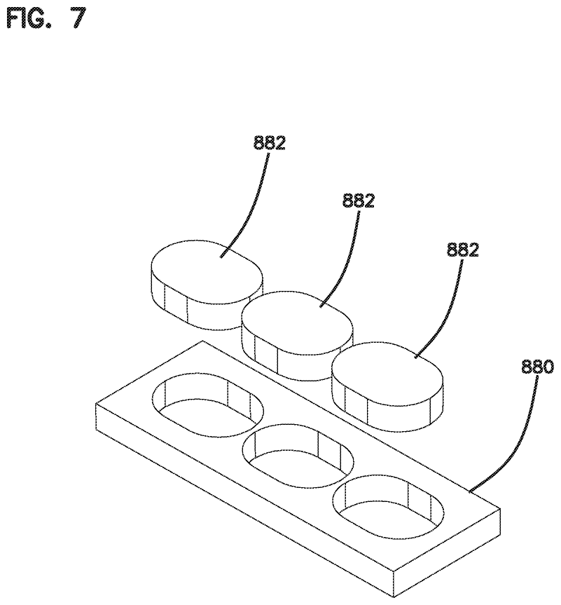

FIGS. 6-7 show another volume compensation plate 880 which has been modified to include resilient inserts 882 (e.g., foam inserts or plugs) that fit within the gel receiving openings 884 of the volume compensation plate 880. During gel pressurization, the inserts 882 can deform to allow gel to flow into the openings 884.

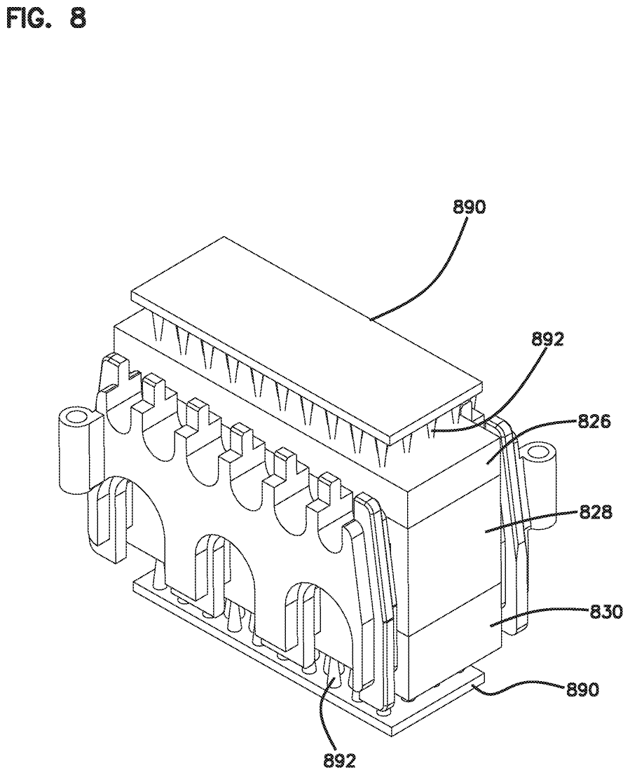

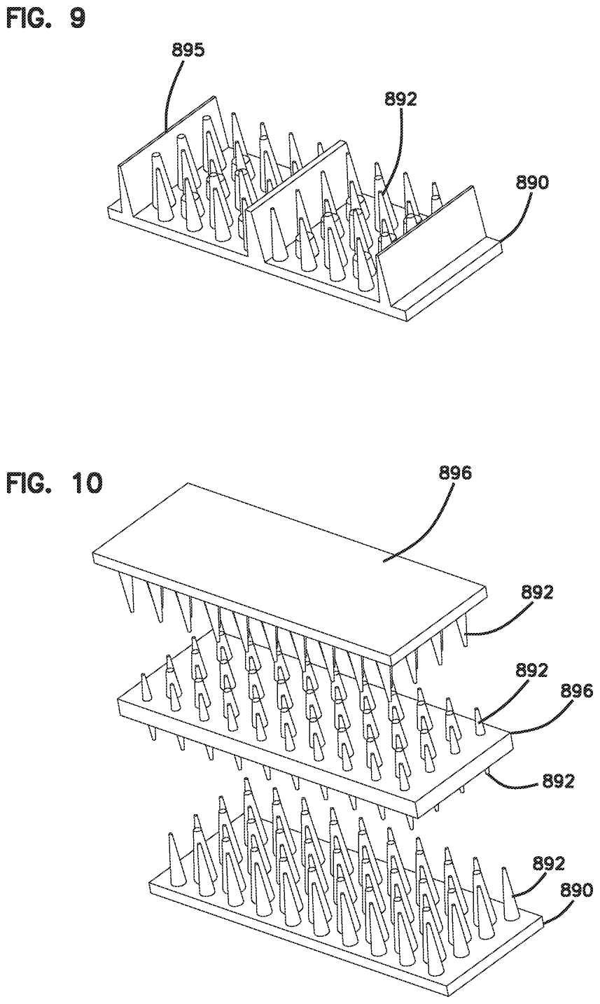

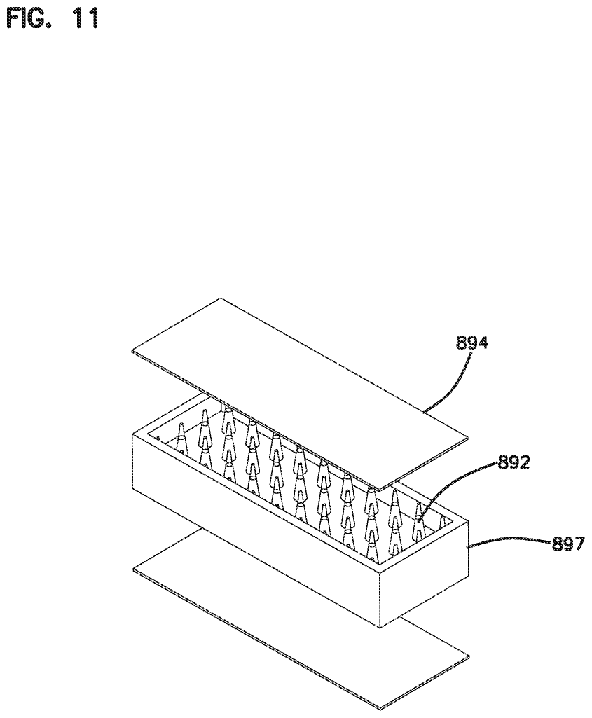

FIGS. 8-11 show another volume compensation plate 890 which has been modified to include open space between tapered projections 892 into which gel of the block of gel flows when the block of gel 824 deforms during sealing. The tapered projections 892 are configured such that a cross-sectional area of the open space reduces as the gel flows into the open space. The tapered projections have free ends at minor ends of the tapered projections and base ends at major ends of the tapered projections. The base ends of the tapered projections are formed with a plate. The tapered projections can be cone-shaped or truncated coned-shaped. When the gel presses between the projections during deformation, the gel moves from the minor ends toward the major ends. In this way, the reduction in the cross-sectional area of the void space between the projections caused by the taper generates a force which biases the deformed gel toward the minor ends. FIG. 10 shows a version where plates 890 are positioned between the first and third gel sections 826, 830 and the first and second housing pieces 804, 806, and a plate with double sided tapered projections is also used within the second gel section 828. FIG. 11 shows a version were the cones 892 are surrounded by a volume defining wall 897 and the empty space within the wall 897 is cover by at least one cover layer 894. Also, as shown at FIG. 9, tapered spring member projections 895 can be configured to flex when contacted by pressurized gel to apply spring load to the gel.

Aspects of the present disclosure relate to sealing arrangements such as gel sealing arrangements that include relatively tear or damage resistant sealants. In certain examples, the sealant can have mechanical properties and sealing properties demonstrated by the type of gel disclosed in U.S. Pat. No. 8,642,891.

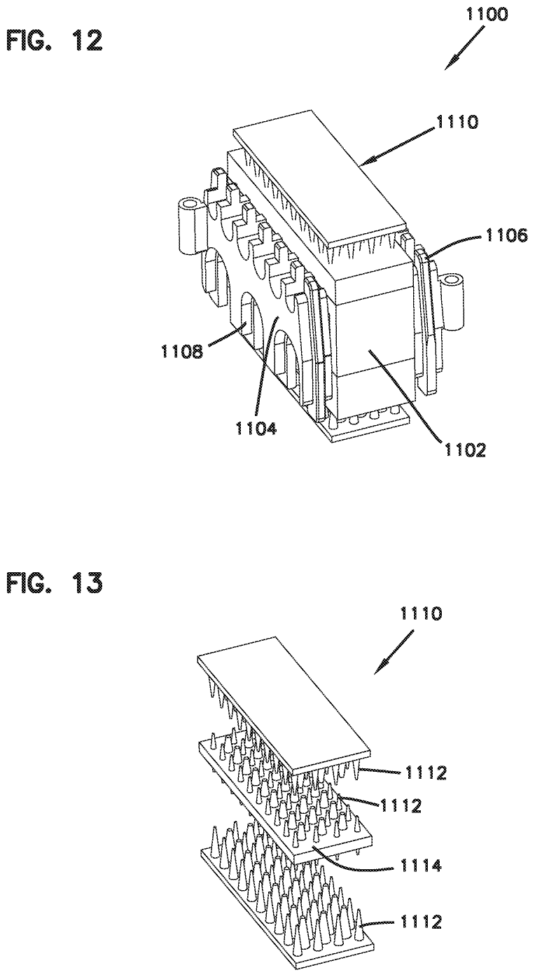

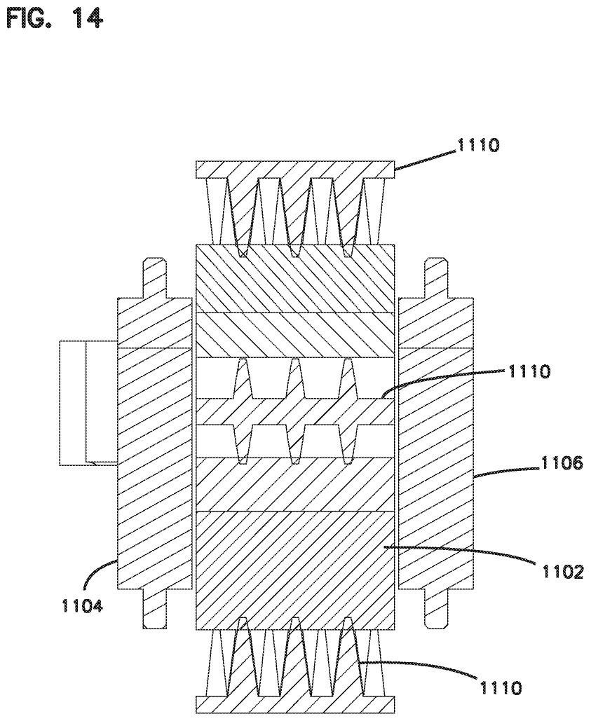

FIG. 12 shows an example cable sealing arrangement 1100 in accordance with the principles of the present disclosure. The cable sealing arrangement 1100 includes a volume of sealant 1102 such as a gel. An example gel can include a dry silicone gel as disclosed by U.S. Pat. No. 8,642,801. The sealant 1102 is contained between inner and outer containment walls 1104, 1106. The inner and outer containment walls 1104, 1106 define openings or recesses 1108 for allowing fiber optic cables to be routed there through. The cable sealing arrangement further includes a volume compensation arrangement 1110 (see FIG. 13) including a bed of tapered elements 1112. As depicted, the tapered elements 1112 include truncated cones. Open space 1114 for accommodating deformation of the sealant 1102 when the sealant is pressurized is provided between the tapered elements 1112. The open space 1114 is the void region between the various tapered elements 1112. Typically, the sealant 1102 is initially pressurized by pressurization structures to initially at least slightly deform the sealant 1102. Example pressurization structures can be different parts of an enclosure such as a cover and a base that are moved together such that the sealant 1102 is pressurized between them. Other pressurization structures can include end caps or plates or other structures that are moved together. In certain examples, the pressurization structures move in coordination with opening or closing an enclosure.

In certain examples, the distribution of tapered elements 1112 functions to evenly distribute and control the displacement of the sealant 1102 during initial pressurization of the gel, and during subsequent increases in pressurization as cables are added to the cable sealing arrangement 1100. In certain examples, the sealant stretches over the tapered elements which assists in maintain compression. In certain examples, the system is energized or pressurized initially by closing a lid or cover of an enclosure through external latches. In certain other examples, the sealant is de-pressurized by opening the latches corresponding to the lid or cover.

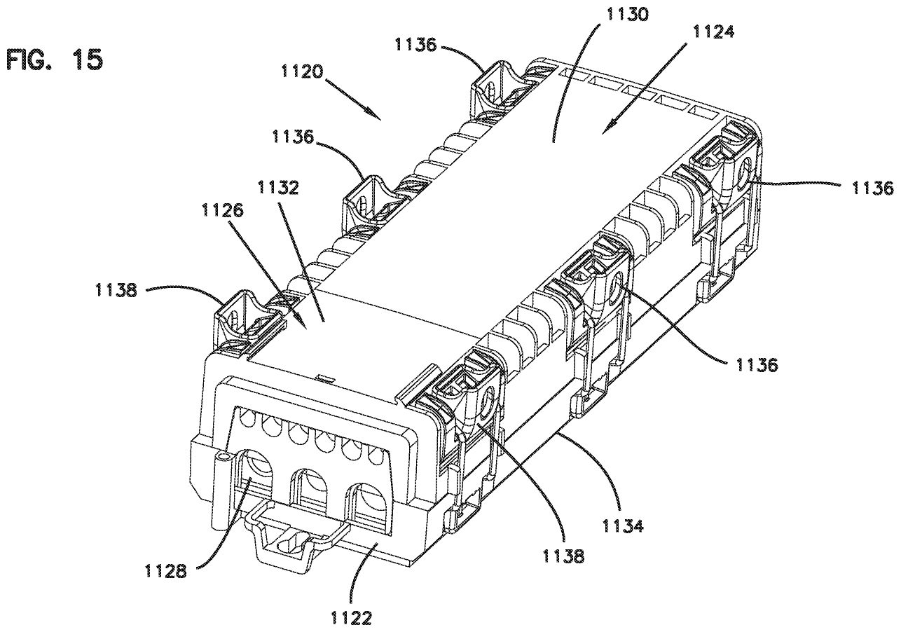

FIG. 15 illustrates a telecommunications enclosure 1120 in accordance with the principles of the present disclosure. The telecommunications enclosure 1120 has a cable access end 1122 through which cables are routed to direct the cables into the interior of the enclosure 1120. It will be appreciated that a cable sealing arrangement 1128, or alternatively the cable sealing arrangement 1100 or other type of sealing arrangement, can be mounted within the enclosure 1120 adjacent the cable access end 1122. The telecommunications enclosure 1120 includes a main section 1124 and a cable sealant pressurizing section 1126. The cable sealing arrangement 1128 is mounted within the cable sealant pressurization section 1126 adjacent the cable access end 1122. The telecommunications enclosure 1120 includes a first cover 1130 corresponding to the main section 1124 and a second cover 1132 corresponding to the cable sealant pressurization structure 1126. The first and second covers 1130, 1132 are each mounted on the same base 1134. First latches 1136 are used to latch the first cover 1130 on the base 1132. Second latches 1138 are used to latch the second cover 1132 on the base 1134. The latches 1136 can be independently opened with respect to the latches 1138 and vice versa. Thus, the first cover 1130 can be opened while the second cover 1132 remains closed. In certain examples, a perimeter seal can be provided around the perimeter of the enclosure at the interface between the first and second covers 1130, 1132 and the base 1134. Additionally, a seal can be provided between the first and second covers 1130, 1132.

In certain examples, by opening the first cover 1130, access to the interior of the main section 1124 can be obtained. In certain examples, optical components such as splice trays, fiber optic splitters, demateable fiber optic connection locations (e.g., fiber optic adapters coupling together fiber optic connectors) and other structures can be provided within the main section 1124. Preferably, the cable sealing arrangement 1128 is positioned within the cable sealant pressurization section 1126. Preferably, the cable sealing arrangement 1128 is pressurized when the latches 1138 are used to secure the second cover 1132 closed against the base 1134. Preferably, the cable sealing arrangement 1128 is not depressurized when the latches 1136 of the first cover 1130 are open while the latches 1138 of the second cover 1132 remain closed.

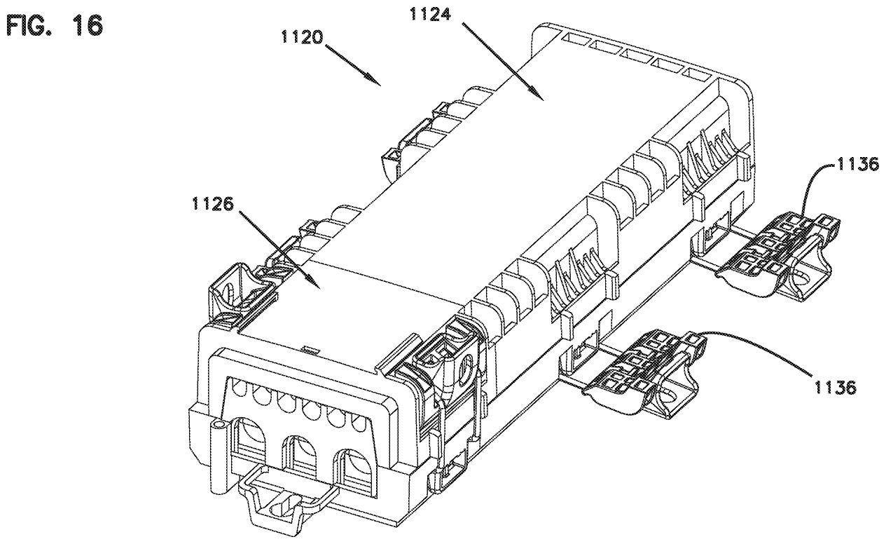

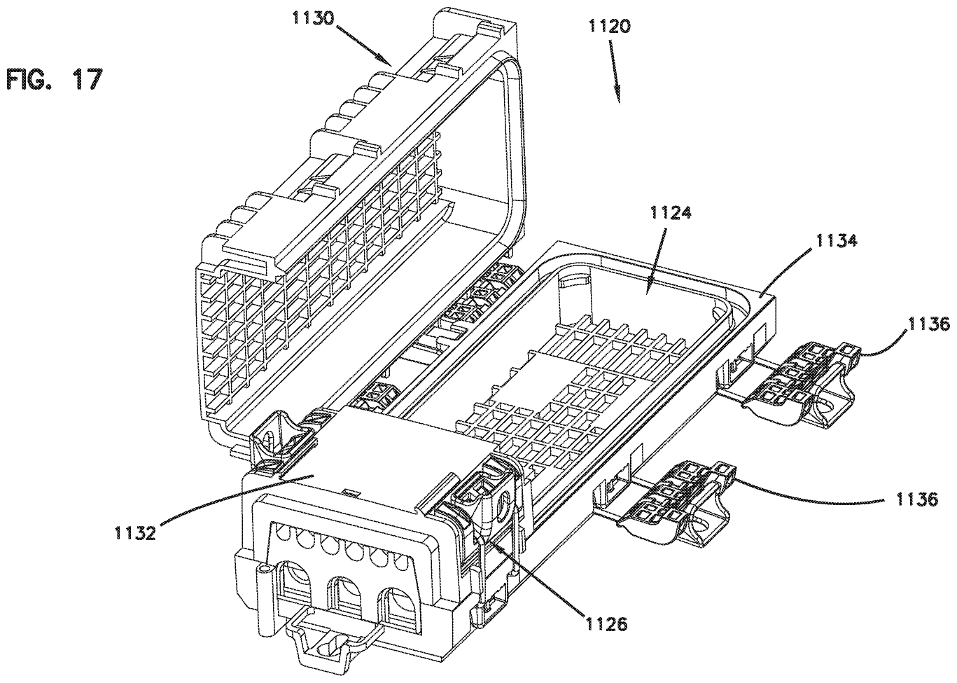

FIG. 16 shows that the main section 1124 of the telecommunications enclosure 1120 can be open while the cable sealant pressurization section 1126 of the enclosure 1120 remains latched closed. FIG. 17 shows the first cover 1130 of the enclosure 1120 pivoted to an open position while the second cover 1132 remains latched closed and the cable sealant arrangement 1128 remains pressurized. With the first cover 1130 open, a technician can access an interior of the main section 1124 to access optical fibers of cables routed into the interior of the enclosure, to perform splicing, to perform patching, or to perform other operations.

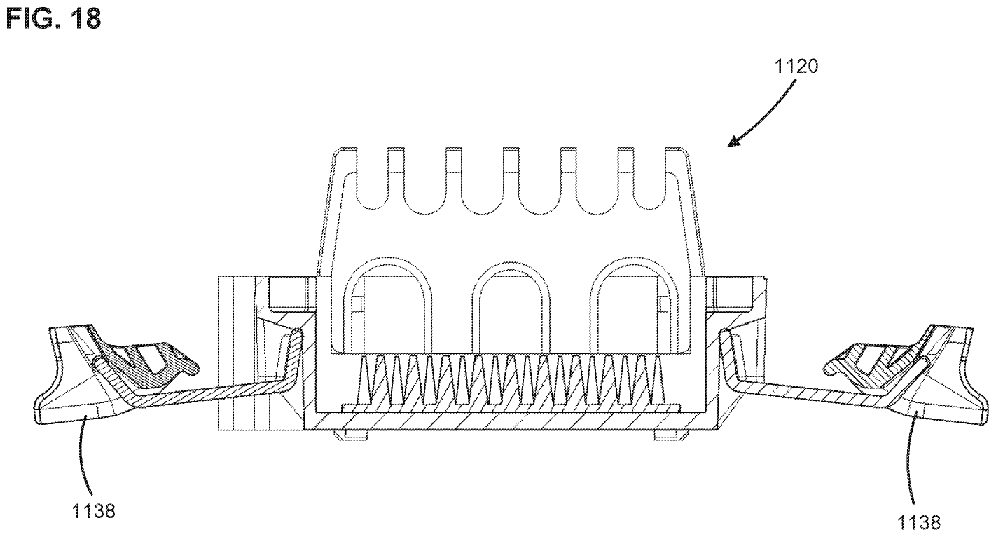

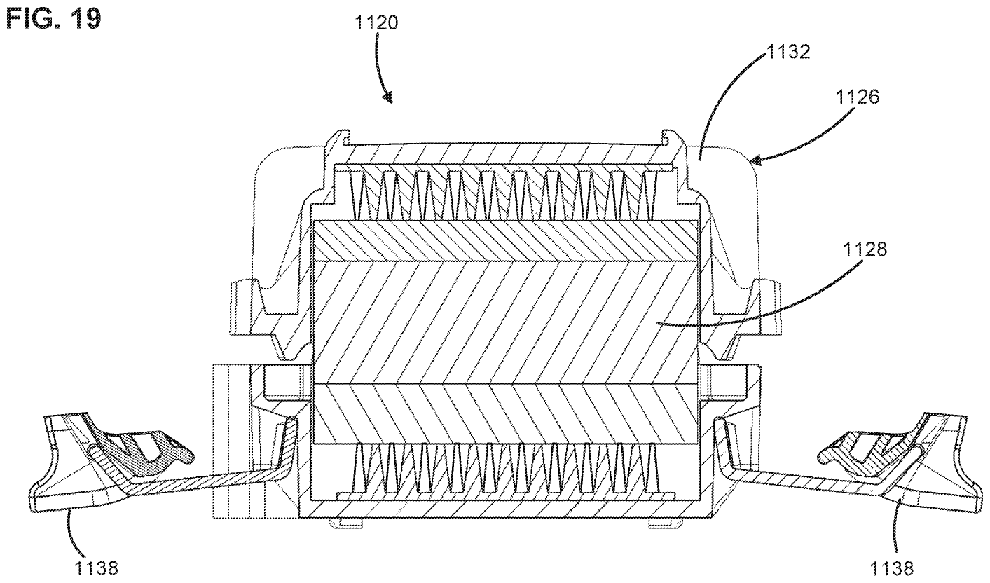

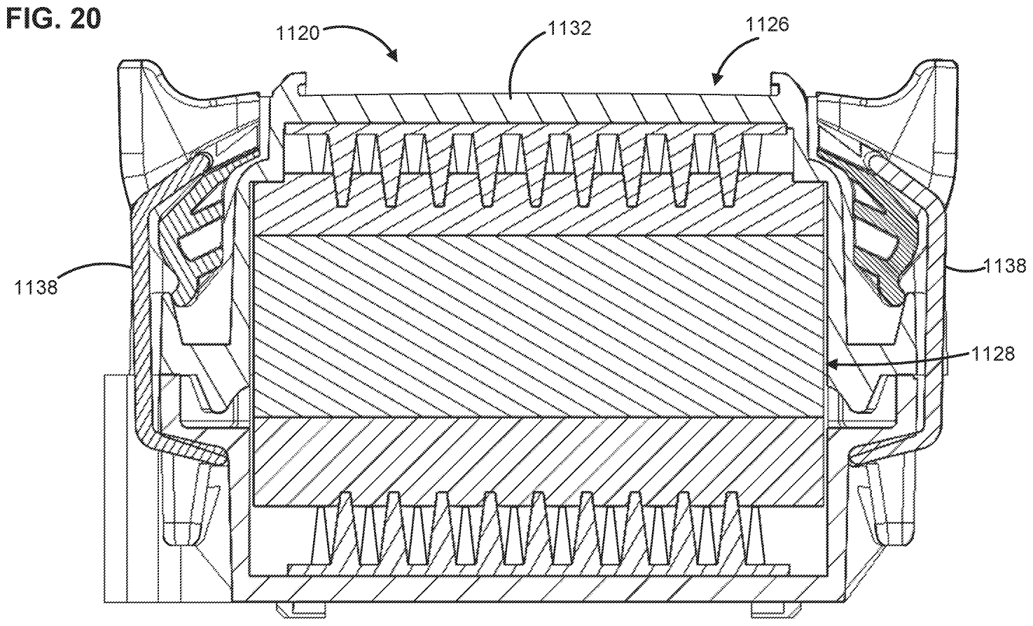

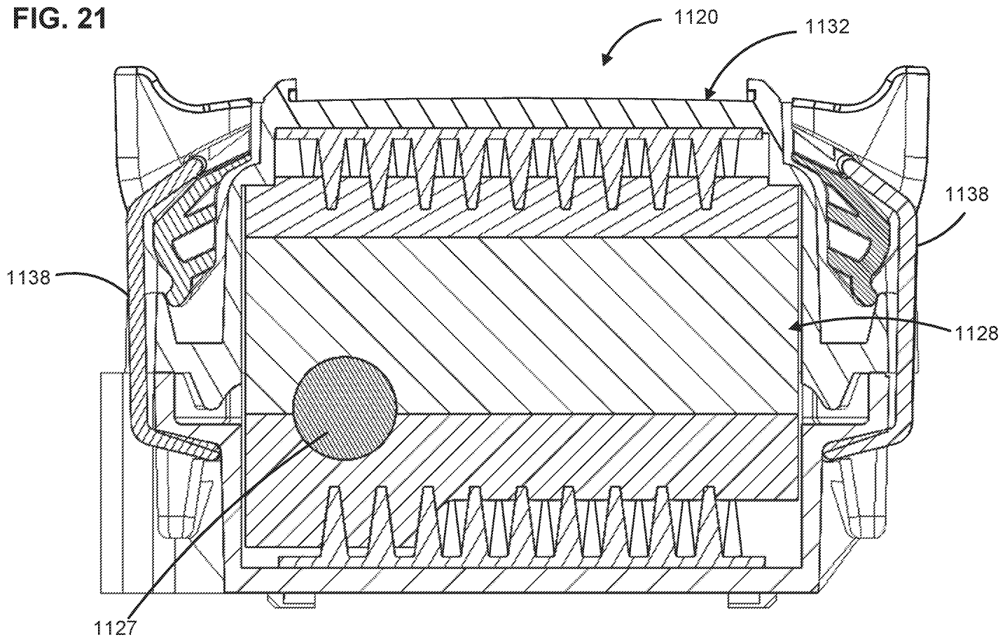

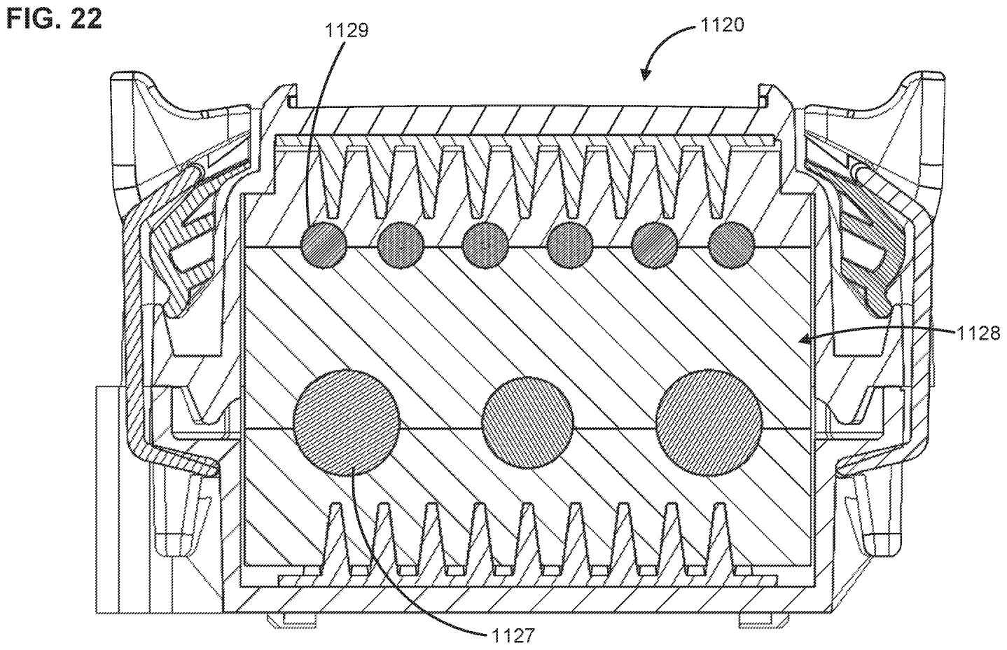

FIG. 18 is a cross-sectional view cut through the cable sealant pressurization section 1126 with the second cover 1132 open and with no sealant present in the cable sealant pressurization section 1126. FIG. 19 is a cross-sectional view cut through the cable sealant pressurization section 1126 with the cable sealant arrangement 1128 positioned therein and with the second cover 1132 unlatched such that the cable sealant arrangement 1128 is not pressurized. FIG. 20 is a cross-sectional view through the cable sealant pressurization section 1126 with the cable sealing arrangement 1128 present within the cable sealant pressurization structure 1126 and with the second cover 1132 latched against the base 1134 by the latches 1138 such that the sealant of the cable sealing arrangement 1128 is initially pressurized. As shown at FIG. 20, when the sealant of the cable sealing arrangement 1128 is pressurized, some of the sealant moves into the void or open space defined between the bed of tapered elements that assist in providing volume compensation for the cable sealing arrangement 1128 while maintaining uniform pressurization of the sealant. FIG. 21 is a cross-sectional view through the cable sealants pressurization section 1126 with a cable 1127 sealed within the cable sealing arrangement 1128. When the cable is added to the cable sealing arrangement 1128, the volume of the cable within the cable sealing arrangement displaces sealant and causes some of the sealant to form or flow into the void spaces between the tapered elements of the volume compensation arrangement. FIG. 22 shows that when additional cables 1127, 1129 are added to the pressurized cable sealing arrangement 1128, the volumes of the cables within the sealant displace additional sealant thereby causing more sealant to flow into the void areas between the tapered elements of the volume compensation arrangement. As shown at FIG. 22, a substantial portion of the open space between the tapered elements has been filled with sealant.

Aspects of the present disclosure relate to systems, tools and operations for allowing fiber optic cables to be installed through a cable sealing arrangement without requiring the cable sealing arrangement to be depressurized or de-energized, and without requiring the cable sealing arrangement to be disassembled. In certain examples, a detackifier can be used to facilitate inserting a cable through the pressurized cable sealing arrangement. Example detackifiers can include cleaning surfactants such as detergents or soaps. It will be appreciated that such detackifiers can be applied with individual wipes, with a rag, by a spraying operation, or by other techniques. It will be appreciated that such surfactants can facilitate sliding a fiber optic cable or other cable through a pressurized volume of sealant, but dissipate over time so as to not interfere with sealing of the cable. In certain examples, a predefined pilot hole can be manufactured through the sealant at the time the cable sealing arrangement is manufactured. Alternatively, a pilot hole or other type of hole can be made through the sealant in the field to facilitate inserting the fiber optic cable there through.

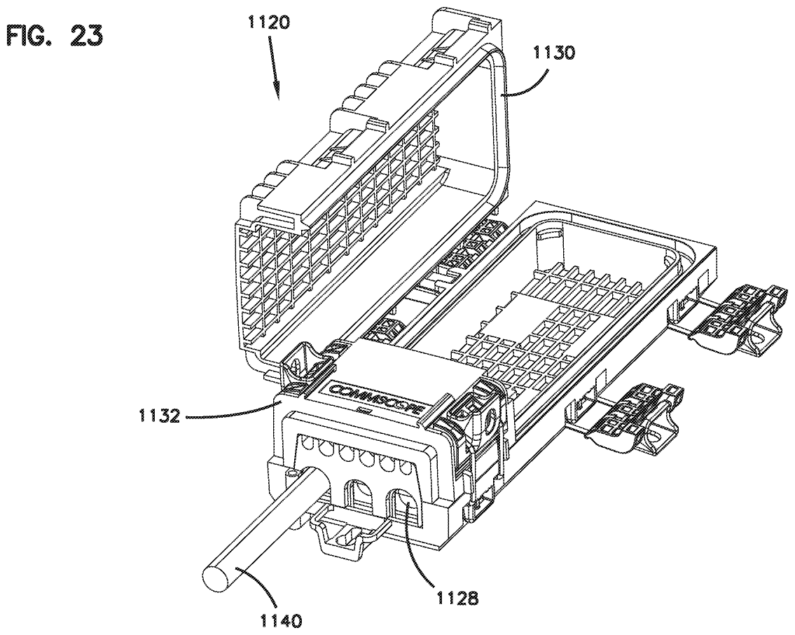

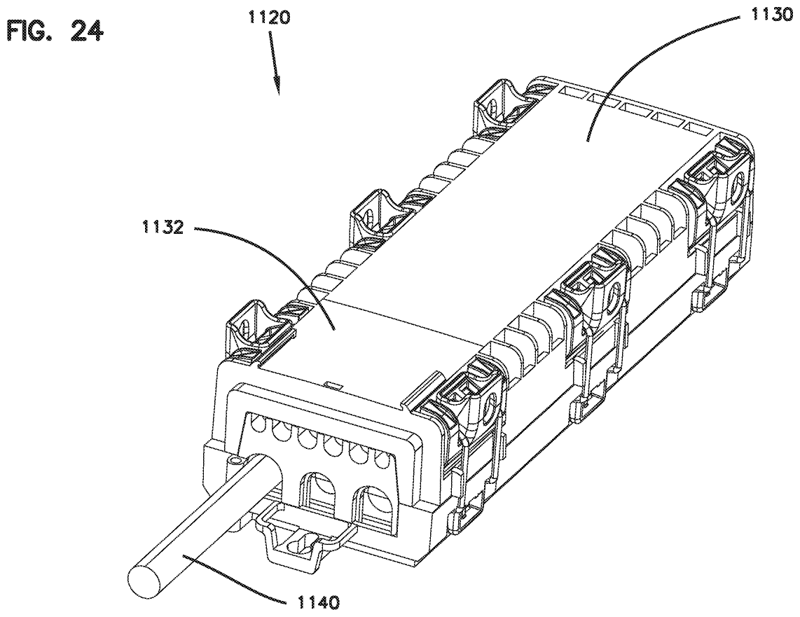

FIG. 23 shows the telecommunications enclosure 1120 in the process of installing a feeder cable 1140 through the cable sealing arrangement 1128. According to this process, the first cover 1130 is open to access the interior of the enclosure 1120, while the second cover 1132 remains closed such that the cable sealing arrangement 1128 is not depressurized during cable installation. It will be appreciated that a cleaning surfactant can be applied to the cable 1140, and then the cable can be pushed through the cable sealing arrangement 1128. In certain examples, the cable 1140 is pushed through a pilot opening made through the sealant of the cable sealing arrangement 1128. Once the cable 1140 is pushed through the cable sealing arrangement 1128, the optical fibers of the cable 1140 can be accessed within the interior of the enclosure 1120 at the main section 1124 for splicing, connectorization, or other applications. Additionally, the cable can be anchored to the enclosure (e.g., strength members of the cable are fixed relative to the closure). Once the optical fibers of the cable have been processed within the interior of the enclosure 1120, the first cover 1130 can be closed to close the main section 1124 as shown at FIG. 24.

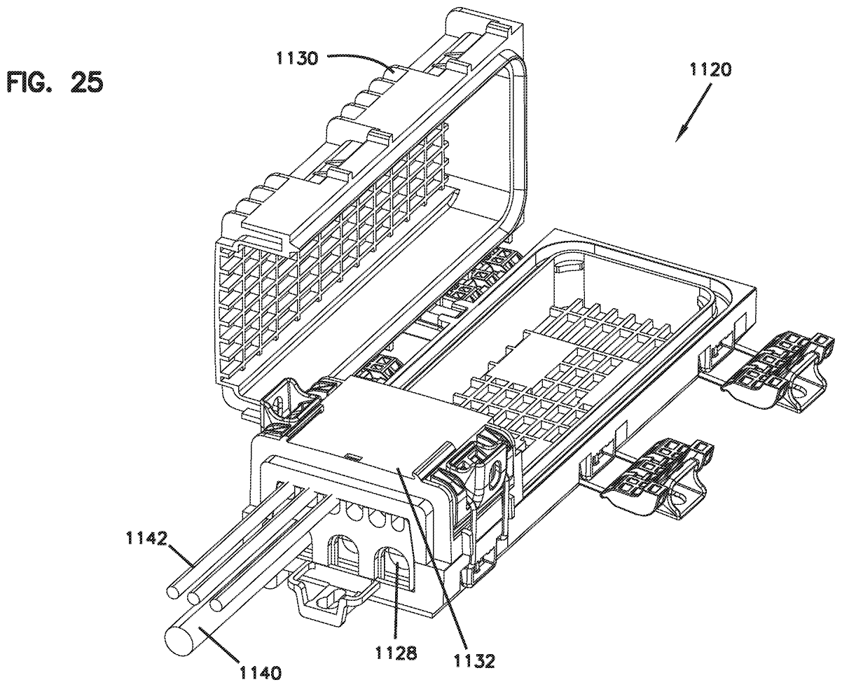

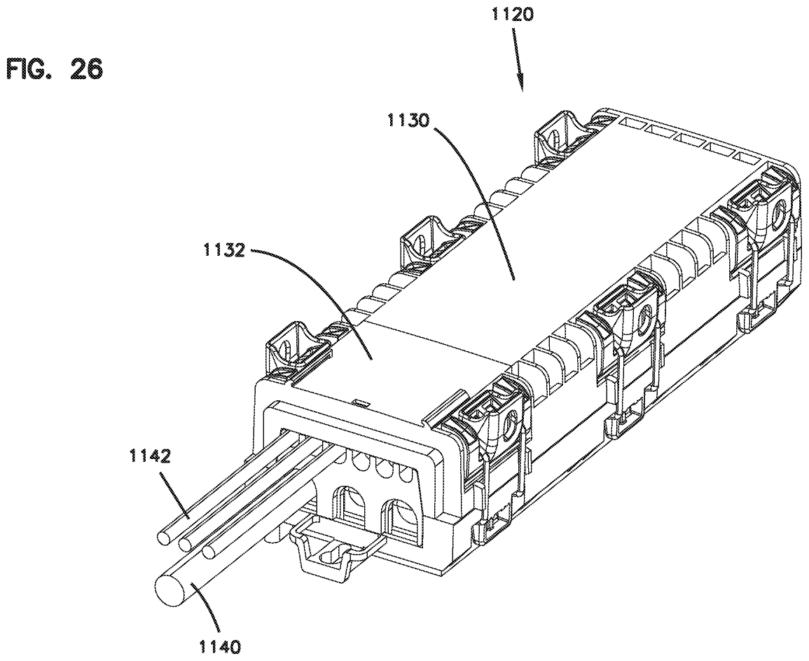

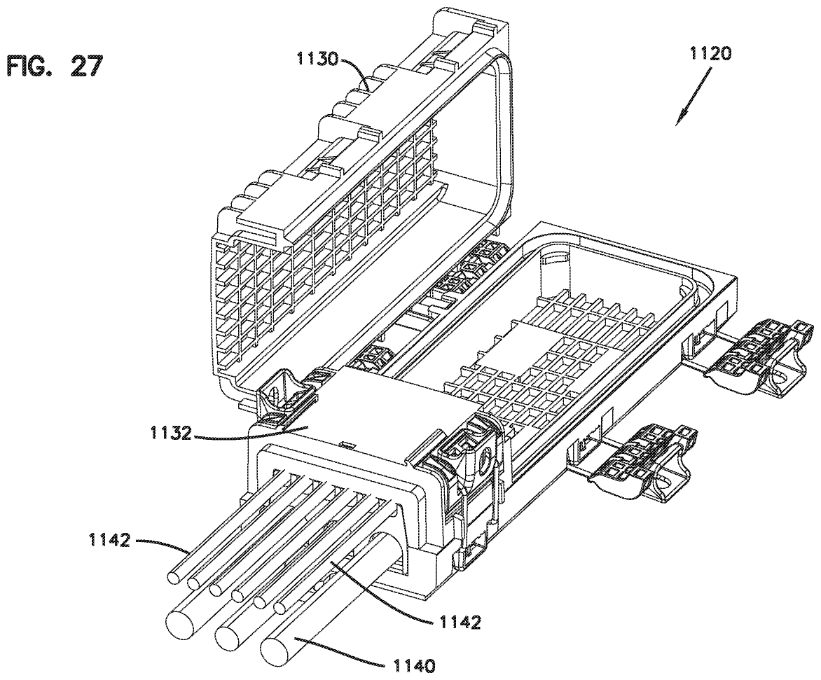

To add additional drop cables 1142 to the enclosure 1120, the process can be repeated as shown at FIG. 25 by reopening the first cover 1130 and pushing drop cables through the sealant of the cable sealing arrangement 1128 while the cable sealant arrangement 1128 remains pressurized (e.g., the latches 1138 of the second cover 1132 remain latched). A cleaning surfactant can be used on the cables to facilitate insertion, and pilot holes can be made through the gel to facilitate insertion. The optical fibers of the drop cables 1142 can be accessed within the interior of the enclosure 1120 through the main section 1124 which is open. For example, optical fibers of the drop cables 1142 can be spliced to optical fibers of the feeder cable 1140. After operations within the enclosure 1120 have been completed, the first cover 1130 of the main section 1124 can be closed as shown at FIG. 26.

To add further feeder cables 1140 and drop cables 1142 to the enclosure 1120, the process can be repeated again by opening the first cover 1130 of the main section 1124 while leaving the second cover 1132 latched closed. With the second cover 1132 latched closed and the cable sealing arrangement 1128 pressurized, the additional cables can be pushed through the sealant of the cable sealing arrangement 1128. Once again, pilot holes and a cleaning surfactant can be helpful in pushing the cables 1140, 1142 through the cable sealing arrangement 1128. After the cables have been pushed into the interior of the enclosure, the cables can be anchored to the enclosure for strain relief and optical fibers of the cables can be accessed for splicing, connectorization, coupling to splitters, wavelength division multiplexers, or for other applications.

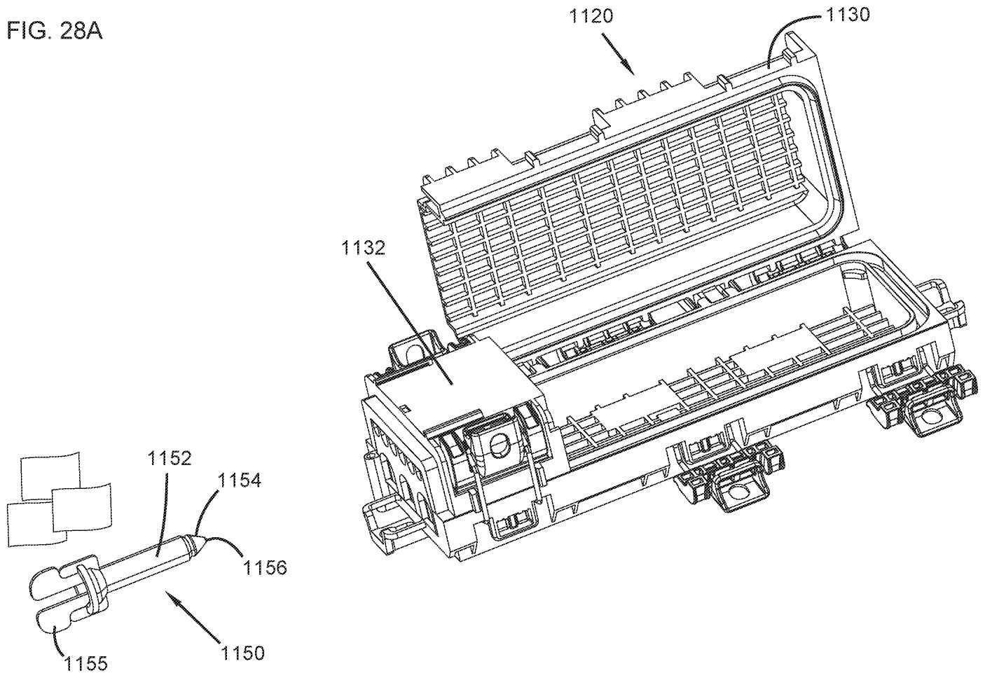

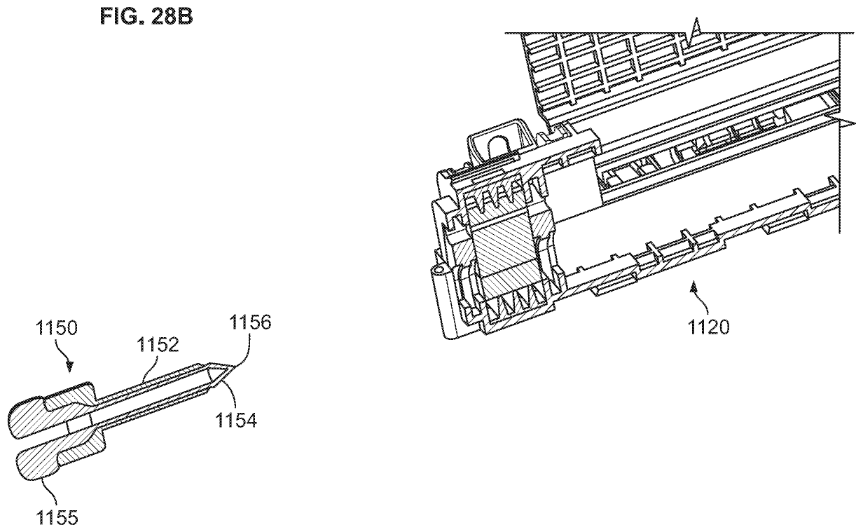

FIGS. 28A and 28A show an example sealant expander tool 1150 for facilitating pushing a cable through the cable sealing arrangement 1128 while the cable sealing arrangement 1128 remains pressurized. The sealant expansion tool 1150 includes a port expander portion 1152 (i.e., a cable guide portion; a hollow portion, a channel-defining structure, etc.) and a core piece 1154 that mounts within the port expander portion 1152. The core piece 1154 can have a pointed tip 1156 for facilitating pushing the port expander tool 1152 through the sealant of the cable sealing arrangement 1128 while the cable sealing arrangement 1128 is pressurized. The pointed tip can project forwardly beyond the front end of the port expander portion 1152. The core piece 1154 can include a rear handle 1155 that is grasped during insertion of the tool 1150 though the sealant, and during removal of the core piece 1154 from the port expander portion 1152 after insertion of the tool through the sealant.

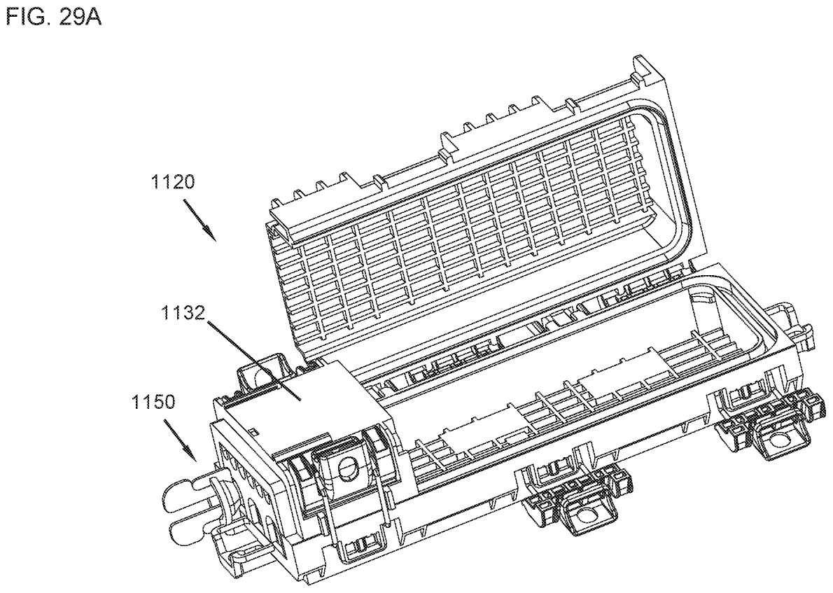

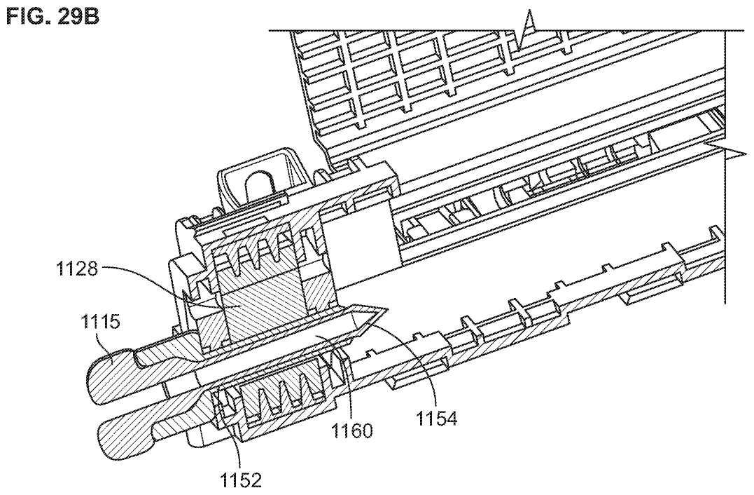

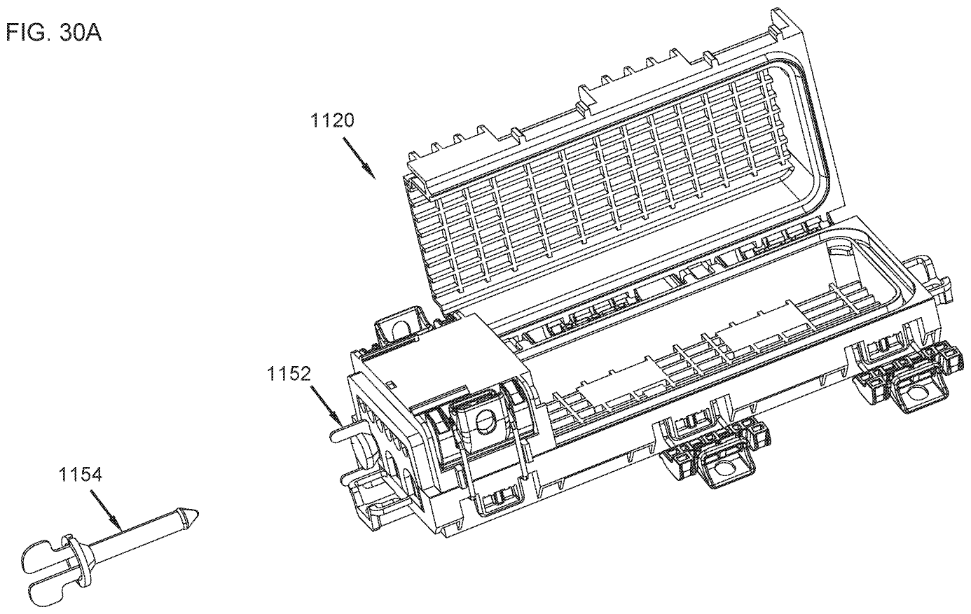

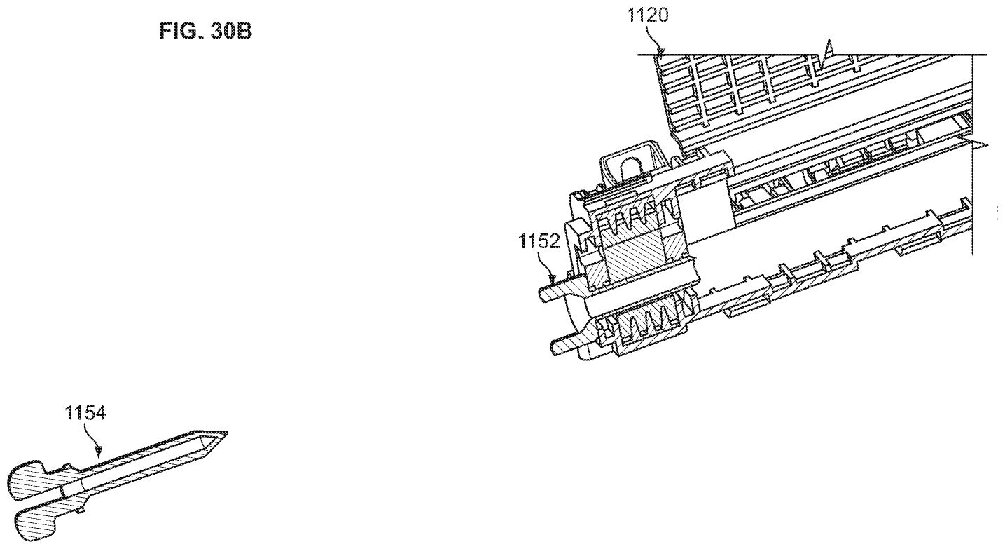

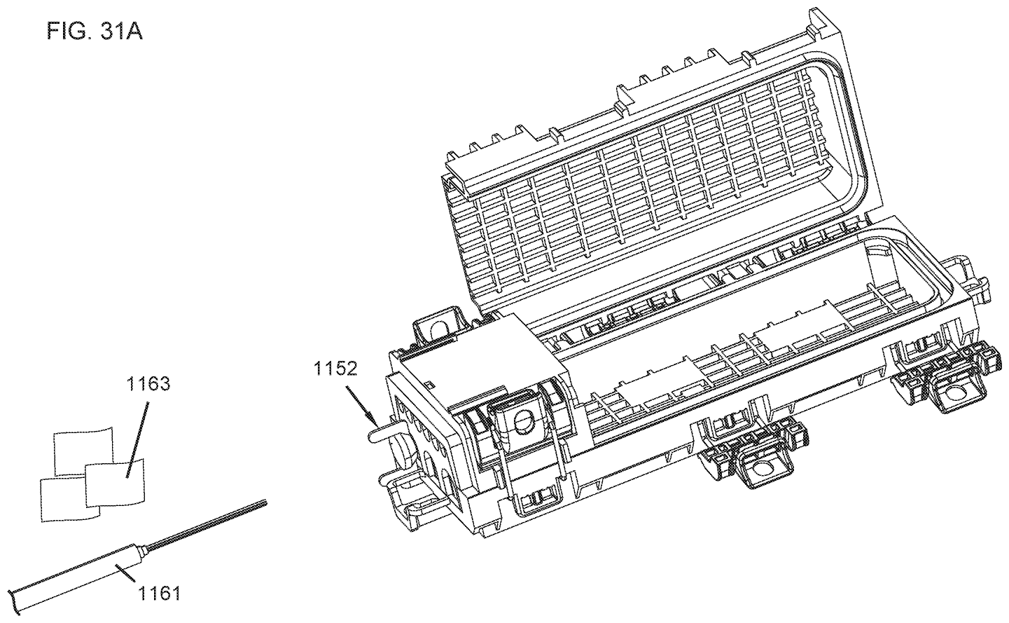

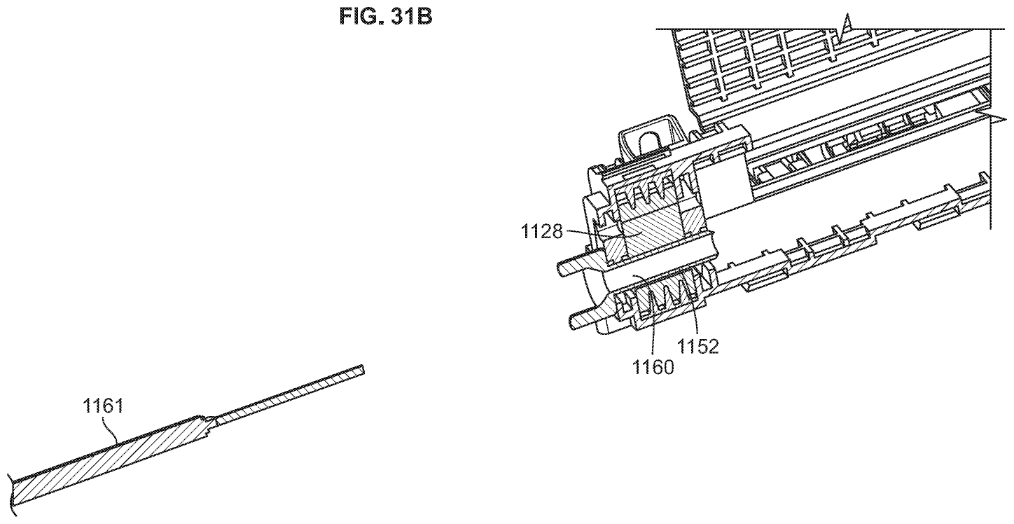

FIGS. 29A and 29A show the port expander tool 1150 pushed through the sealant of the cable sealing arrangement 1128 while the cable sealing arrangement 1128 is pressurized. Once the port expander tool 1150 has been inserted through the cable sealing arrangement 1128, the core piece 1154 can be removed from the port expander portion 1152. The port expander portion 1152 defines a central passage 1160 that extends through the sealant of the cable sealing arrangement 1128 from the outer side of the cable sealing arrangement to the inner side of the cable sealing arrangement 1128. Thus, the passage 1160 provides an enlarged opening suitable for receiving a fiber optic cable 1161 desired to be inserted through the cable sealing arrangement 1128. It will be appreciated that a cleaning surfactant 1163 can be applied to the port expander tool 1152 prior to insertion therein to facilitate the insertion process. In certain examples, the port expander portion 1152 can include two pieces 1152a, 1152b that mate together. In certain examples, the pieces 1152a, 1152b can include half pieces that extend along the entire length of the port expander portion 1152. It will be appreciated that the channel 1160 is defined between the pieces 1152a, 1152b of the port expander portion 1152.

After insertion of the tool 1152 through the sealant, the core piece 1154 can be removed from the port expander portion 1152 by pulling rearwardly on the handle 1155. With the core piece or pin 1154 removed from the port expander portion as shown at FIGS. 38A and 38A, a fiber optic cable 1162 can be inserted through the cable sealing arrangement 1128 while the cable sealing arrangement 1128 is pressurized by inserting the cable 1162 through the channel 1160 defined by the port expander portion 1152. In certain examples, a cleaning surfactant can be applied to the cable 1162 to facilitate the insertion process. In certain examples, if the cable 1162 is larger than the cross-dimension of the channel 1160, the pieces 1152a, 1152b of the port expander portion 1152 can move apart during the insertion process to accommodate the larger cable.

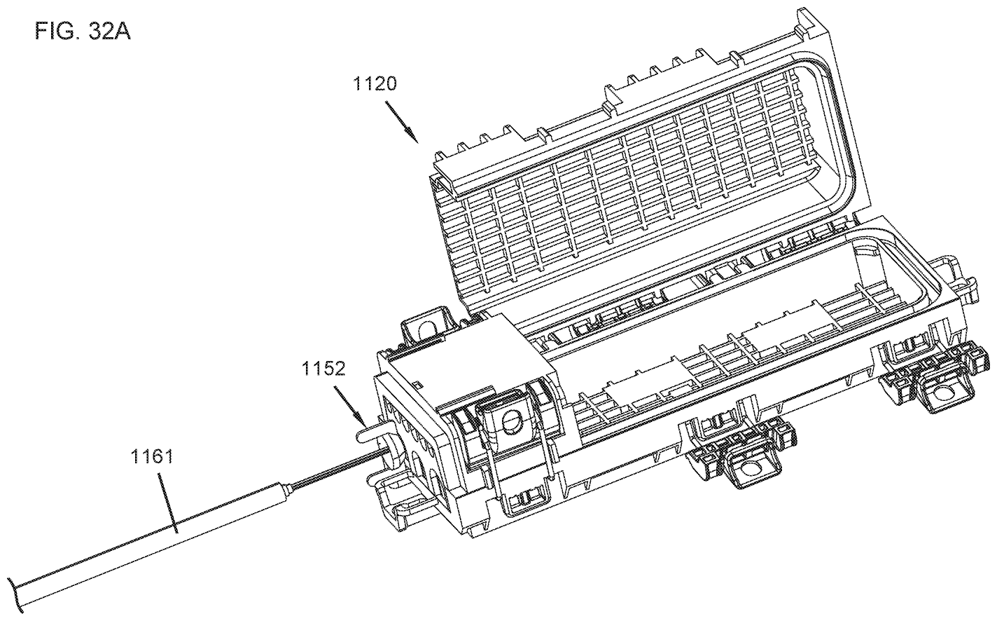

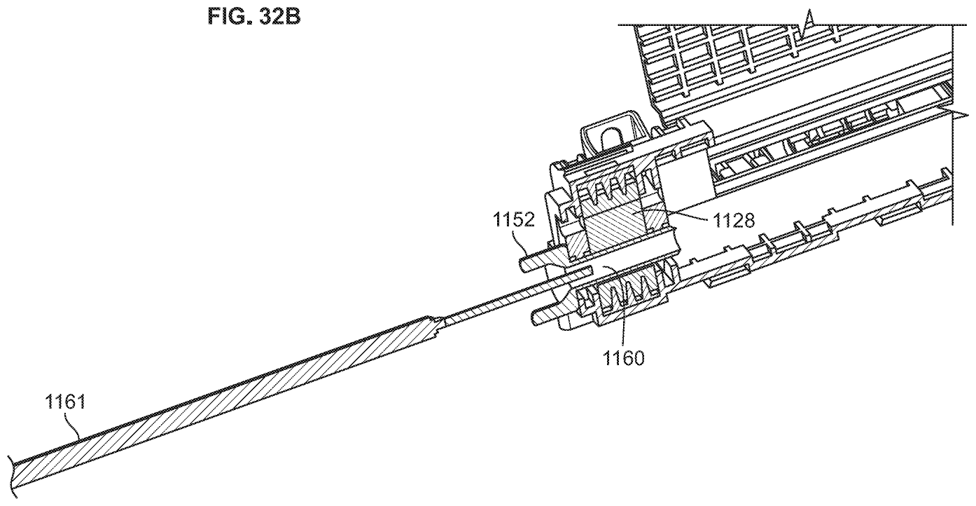

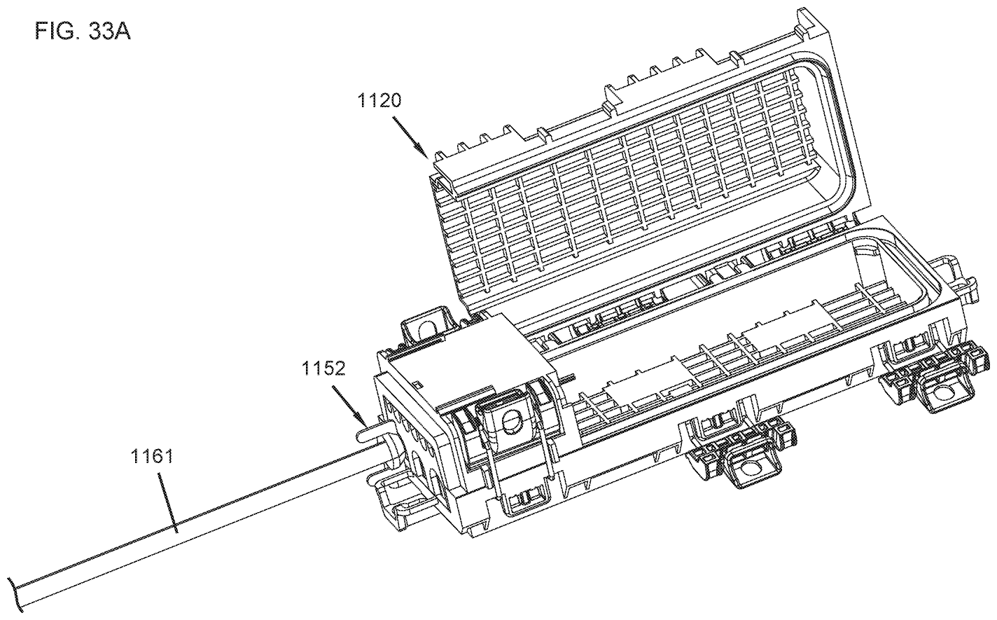

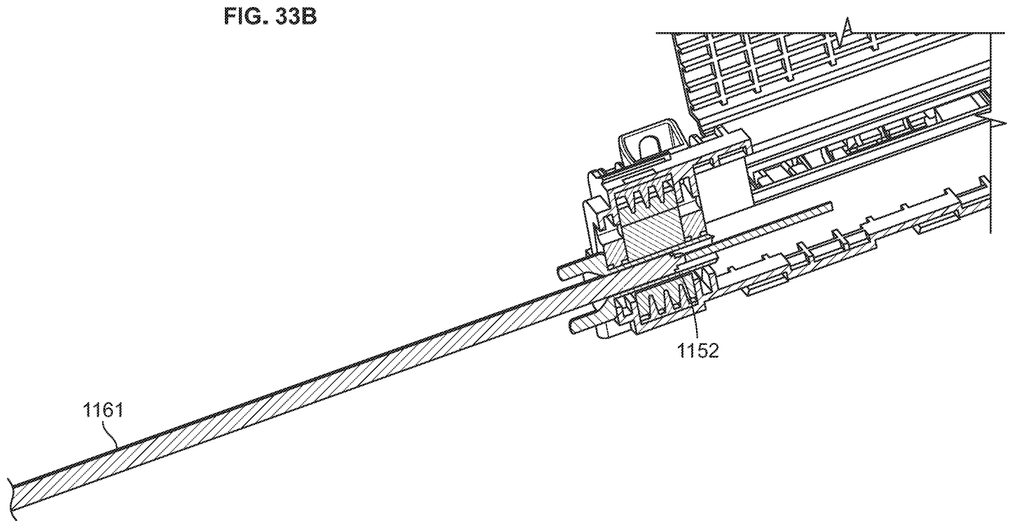

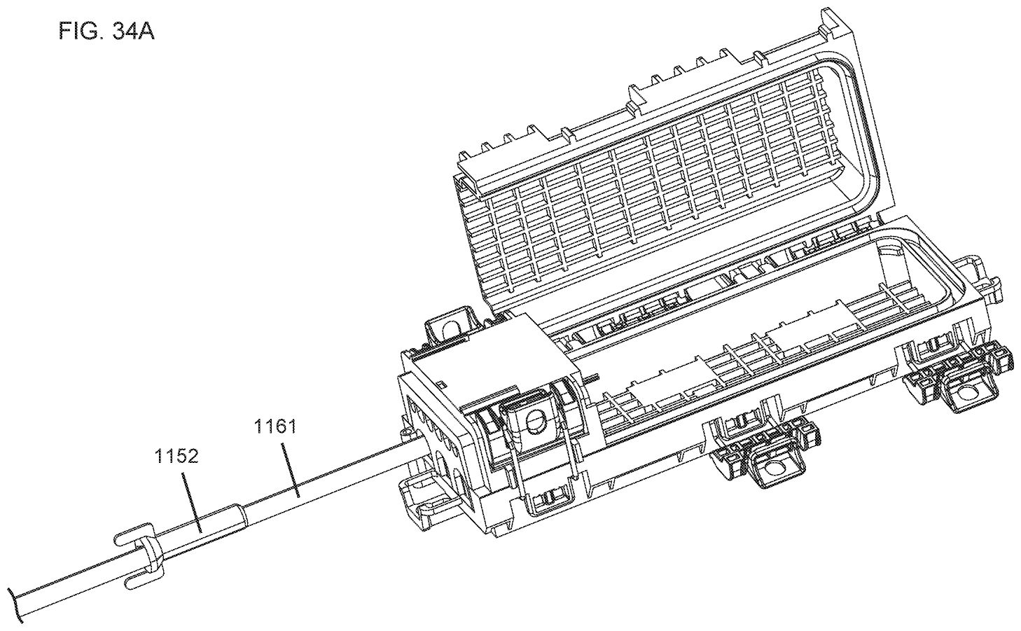

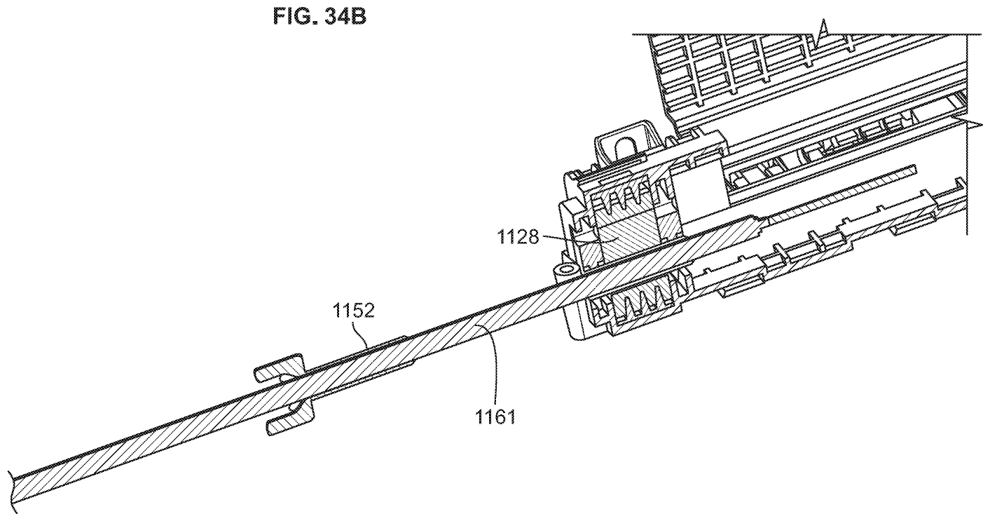

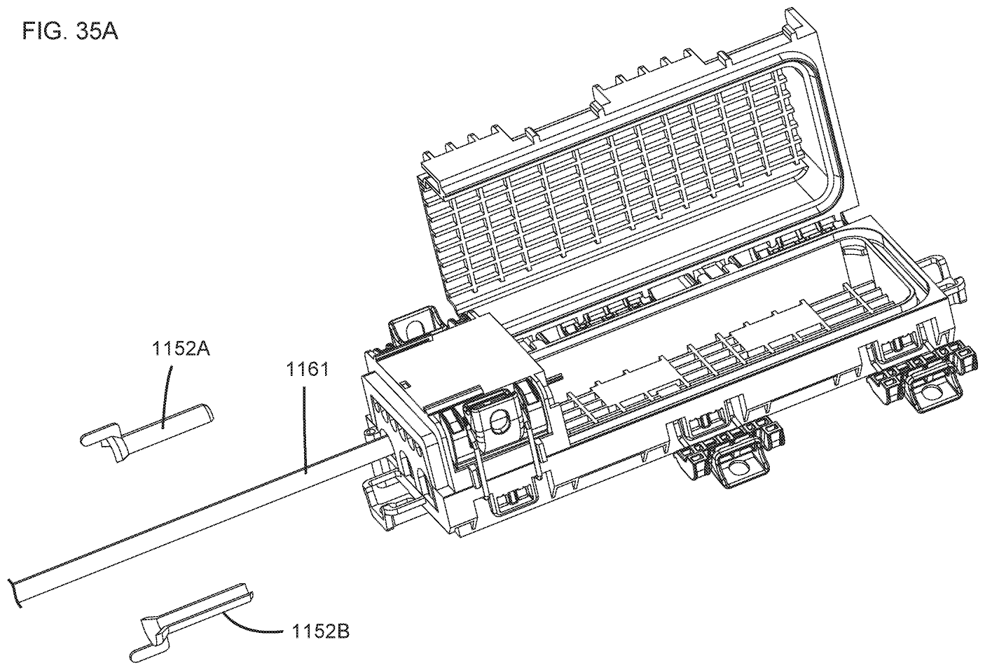

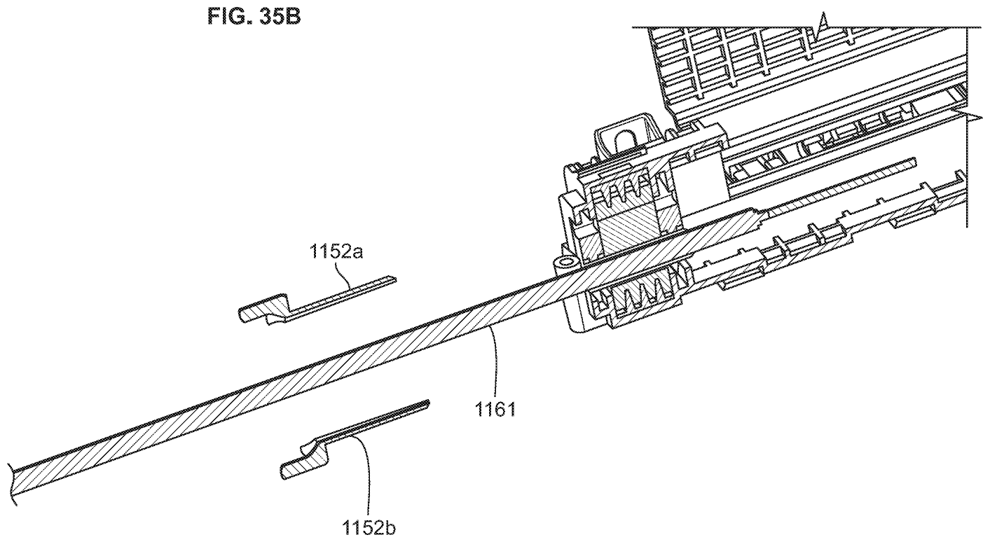

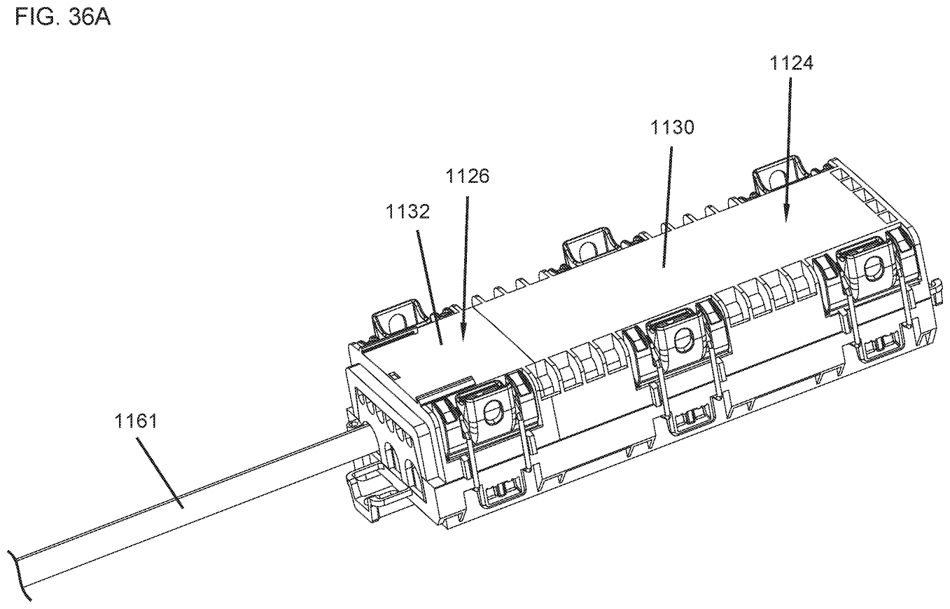

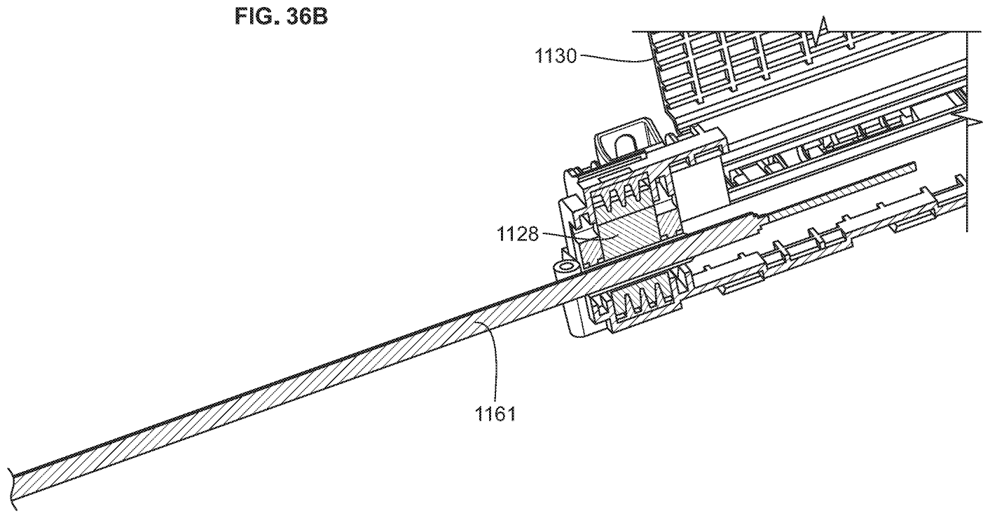

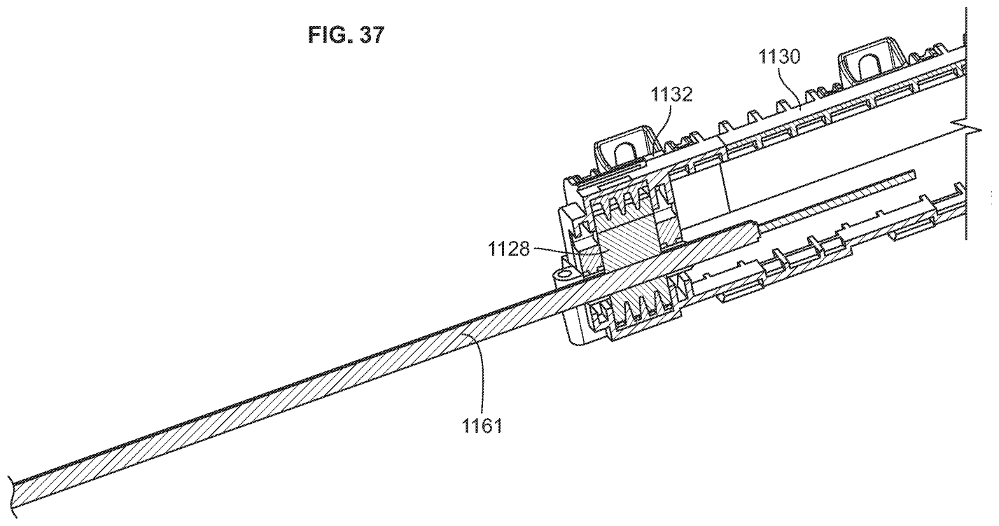

FIGS. 32A, 32B, 33A, and 33B show the cable 162 in the process of being inserted through the channel 1160 of the port expander portion 1152. Once the cable 1162 has been pushed into the interior of the enclosure 1120, the cable 1162 can be anchored within the interior of the enclosure 1120 by accessing the cable through the main section 1124. Additionally, optical fibers of the cable 1162 can be accessed within the interior of the enclosure 1120 through the main section 1124. With the cable 1162 installed within the enclosure 1120, the port expander portion 1152 can be removed by pulling the port expander portion 1152 out of the cable sealing arrangement 1128 as shown at FIGS. 34A and 34B. Handles 1157 of the port expander portion 1152 can facilitate pulling the port expander portion 1152 from the cable sealing arrangement 1128. The two-part construction of the port expander portion 1152 allows the port expander portion 1152 to then be removed from the cable 1162 as shown at FIGS. 35A and 35B. Thereafter, the cable 1162 is sealed within the pressurized cable sealing arrangement 1128 as shown at FIGS. 36A, 36B. The installation process is completed by closing the first cover 1130 of the main section 1124 as shown at FIG. 37.

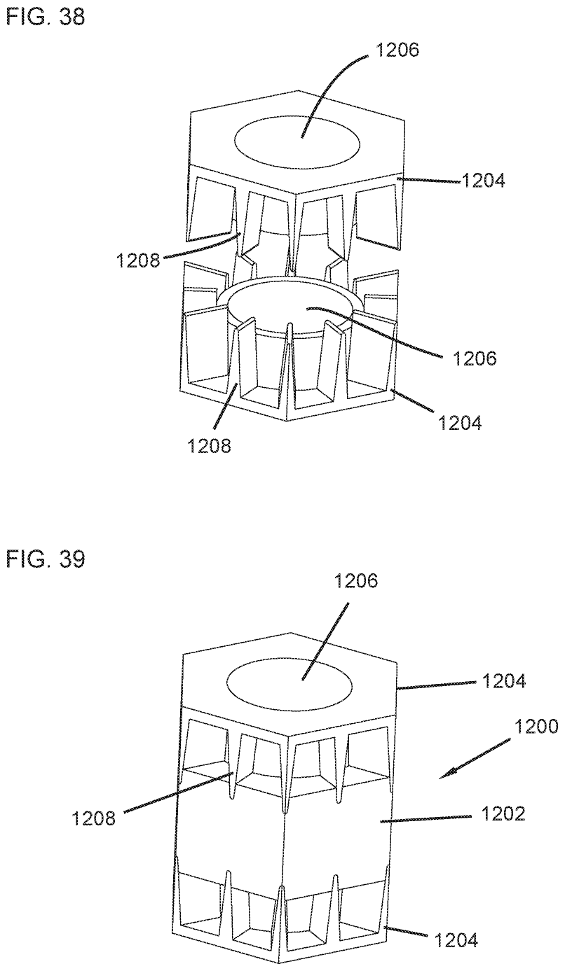

FIGS. 38-40 show an example cable sealing unit 1200 in accordance with the principles of the present disclosure. The cable sealing unit 1200 includes a volume of sealant 1202 axially positioned between two end caps 1204. In certain examples, the end caps 1204 can have the transverse cross-sectional shape of a polygon, as can the volume of sealant 1202. For example, as depicted, the end caps 1204 and the sealant 1202 can have a hexagonal transverse cross-sectional shape. Each of the end caps 1204 includes a center port defining portion defining an opening 1206 sized for receiving a cable. Additionally, each of the end caps 1204 includes sealant volume compensation structures such as tapered elements 1208.

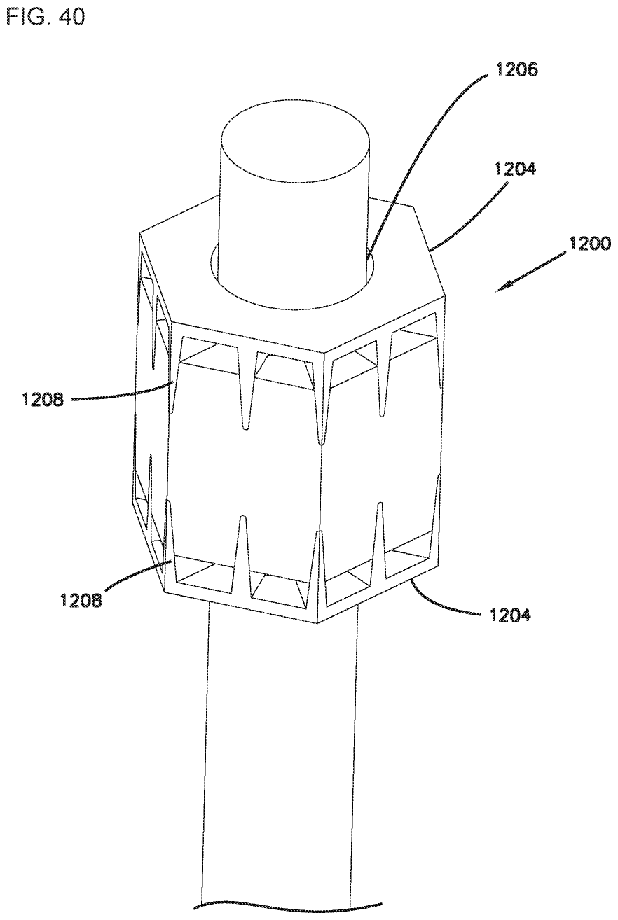

In certain examples, cable sealing units 1200 can be used in combination with an enclosure such as a dome-styled enclosure 1212 (see FIG. 41). The dome style enclosure 1212 includes a dome 1214 and a base 1215 that are coupled together by a clamp 1216. In certain examples, the clamp 1216 can have a V-shaped or tapered internal cross-section that functions to compress flanges of the base and the dome together. As shown at FIG. 43, base 1214 can include pockets 1218 having shapes that match the shapes of the sealant and the end caps 1204 (e.g., hexagonal transverse cross-sectional shapes). For example, pockets can be hexagonal to provide enhanced space usage.

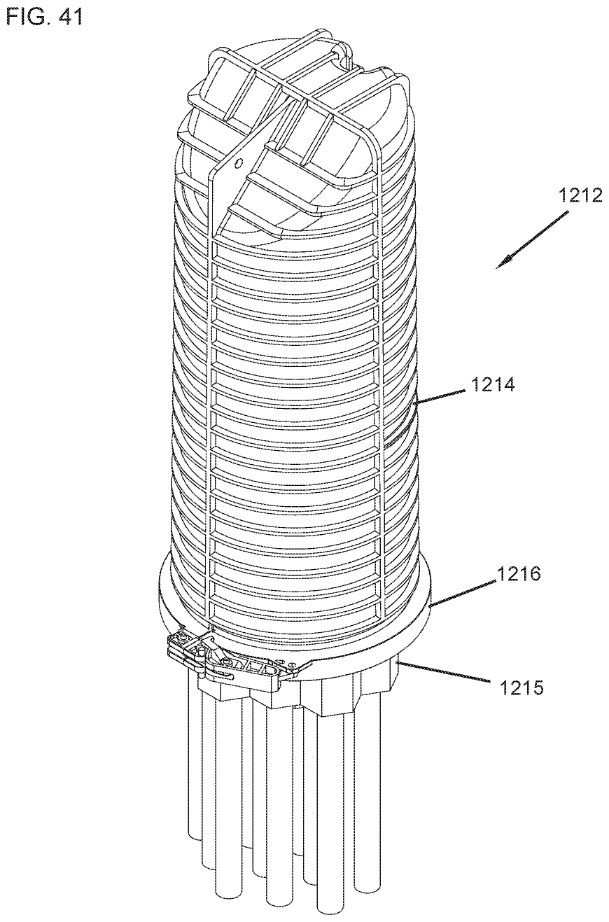

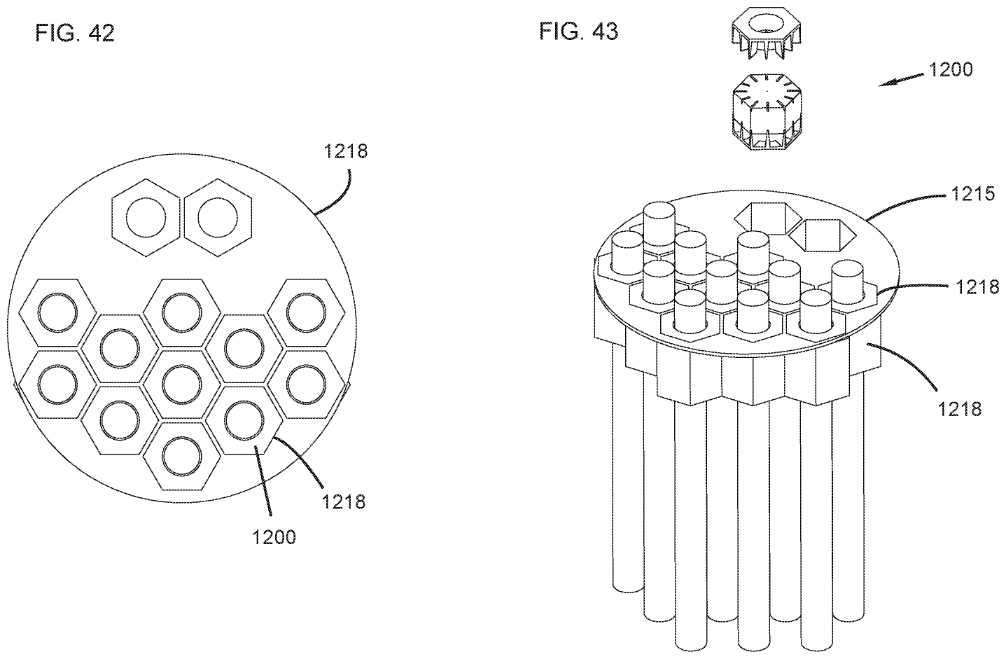

In certain examples, the cable sealing units 1200 are mounted within the pockets 1218 and are pressed into the pockets to pressurize the sealant 1202 by an internal plate (not shown). In certain examples, it will be appreciated that the end caps 1204 may be integrated or made unitary within the pockets of the base 1214 and/or with the pressurization plate. It will be appreciated that the pockets 1218 can be arranged in various configurations. FIG. 42 shows a configuration with 11 pockets 1218 arranged in close proximity to one another with adjacent sides parallel to one another, and with two additional pockets 1220, 1222 offset from the remainder of the pockets for providing the functionality of an oval port.

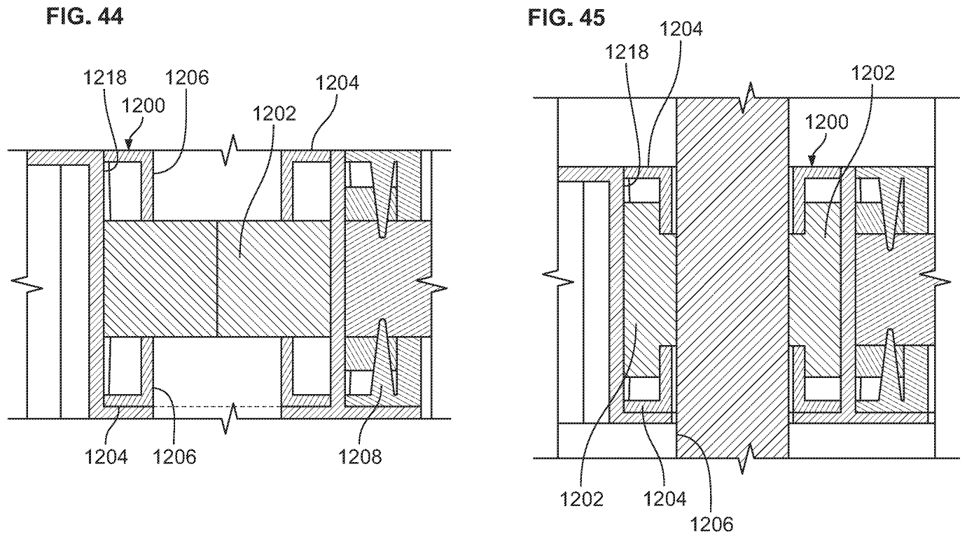

In certain examples, a separate structure such as an internal clamp can be used to press the pressurization plate toward the base plate 1214. Therefore, in certain examples, the clamp 1216 can be released to disengage the dome 1212 from the base 1214 without de-energizing the cable sealing units 1200. In certain examples, cables can be inserted through the sealant 1202 of the cable sealing unit 1200 without depressurizing the sealant 1202 in the same way previously described herein. As the fiber optic cables are inserted through the cable sealing units 1200, the volume of sealant displaced by the cable flows into the open spaces between the tapered members 1208. FIG. 44 shows one of the cable sealing units 1200 prior to insertion of a cable. FIG. 45 shows the cable sealing unit at 1200 after a cable has been inserted there through and the sealant 1202 has flowed into the void spaces between the tapered elements 1208.

Having described the preferred aspects and implementations of the present disclosure, modifications and equivalents of the disclosed concepts may readily occur to one skilled in the art. However, it is intended that such modifications and equivalents be included within the scope of the claims which are appended hereto.

What is claimed is:

1. A method for installing a cable in a cable sealing arrangement which is pressurized within an enclosure, the method comprising:
pushing the cable through sealant of the cable sealing arrangement without de-pressurizing the cable sealing arrangement.

2. The method of claim 1, wherein the enclosure includes a main section having a first cover and a sealant pressurization section having a second cover, wherein the first cover is held closed by a first plurality of latches, wherein the second cover is held closed by a second plurality of latches, wherein the second cover retains the cable sealing arrangement in a pressurized state when the second cover is latched closed, wherein a pressurization state of the cable sealing arrangement is not dependent upon a position of the first cover, and wherein the first cover can be opened to access the fiber optic cable within the enclosure without de-pressurizing the cable sealing arrangement, and wherein the cable can be inserted through the cable sealing arrangement and accessed within the enclosure without ever de-pressurizing the cable sealing arrangement.

3. The method of claim 1, wherein a cleaning surfactant is applied to the cable before pushing the cable through the sealant.

4. The method of claim 3, wherein the cleaning surfactant includes soap or detergent.

5. The method of claim 1, wherein a pilot hole is present in the sealant before the cable is pushed through the sealant.

6. The method of claim 1, wherein the cable is pushed though the sealing while the cable sealing arrangement is pressurized by first inserting an insertion tool though the sealant while the cable sealing arrangement is pressurized and second inserting the cable through the insertion tool while the cable sealing arrangement remains pressurized.

7. The method of claim 6, further comprising applying a cleaning surfactant to the insertion tool prior to inserting the insertion tool through the sealant.

8. The method of claim 6, wherein the insertion tool includes a hollow cable guide and a core piece that fits within the hollow cable guide, and wherein after the insertion tool is inserted through the sealant, the core piece is removed from the hollow cable guide and the cable is then inserted through the hollow cable guide.

9. The method of claim 8, wherein the core piece of the insertion tool has a pointed tip.

10. The method of claim 8, wherein the hollow cable guide includes two pieces that cooperate to define a passage of the hollow cable guide.

11. A system for installing a cable in a cable sealing arrangement which is pressurized within an enclosure, the system comprising:
an insertion tool including a hollow cable guide and a core piece that fits within the hollow cable guide, the hollow cable guide being sized to extend though the cable sealant arrangement, and wherein the core piece is configured to be removed from the hollow cable guide once the insertion tool has been inserted through the cable sealant arrangement to provide clearance for the cable to be passed though the hollow cable guide.

12. The system of claim 11, wherein the core piece of the insertion tool has a pointed tip that protrudes beyond an end of the hollow cable guide when the core piece is mounted in the hollow cable guide.

13. The system of claim 11, wherein the core piece of the insertion tool has a rear handle that is grasped when the insertion tool is inserted through the cable sealing arrangement and that is also grasped when the core piece is removed from the hollow cable guide.

14. The system of claim 11, wherein the hollow cable guide includes two pieces that cooperate to define a passage of the hollow cable guide.

15. The system of claim 11, further comprising a cleaning surfactant for use in applying to the insertion tool and/or the cable.

16. A cable sealing arrangement comprising:
a structure defining a plurality of pockets;
volumes of sealing gel disposed in the pockets;
volume compensation arrangements positioned adjacent at least one end of each pocket, the volume compensation arrangements each including a bed of tapered elements that embed in the sealing gel, wherein open space between the tapered elements is adapted to allow the sealing gel to flow therein upon pressurization of the sealing gel.

17. The cable sealing arrangement of claim 16, further comprising end caps positioned at opposite ends of each pocket with the volumes of sealing gel positioned axially therebetween, the end caps including central cable openings with the tapered elements surrounding the central openings and extending lengthwise in an axial direction.

18. The cable sealing arrangement of claim 16, wherein the pockets have polygon-shaped transverse cross-sectional profiles.

19. The cable sealing arrangement of claim 18, wherein the pockets have hexagon-shaped transverse cross-sectional profiles.

20. The cable sealing arrangement of claim 16, wherein the pockets are integrated in a base of a dome-style enclosure.
